(19) United States
(12) Patent Application Publication
(10) Pub. No.: US 2024/0088252 A1
(43) Pub. Date: Mar. 14, 2024

(54) GATE ALL AROUND TRANSISTORS WITH HETEROGENEOUS CHANNELS

(71) Applicant: INTERNATIONAL BUSINESS MACHINES CORPORATION, ARMONK, NY (US)

(72) Inventors: Andrew M. Greene, Slingerlands, NY (US); Shogo Mochizuki, Mechanicville, NY (US); Julien Frougier, Albany, NY (US); Gen Tsutsui, Glenmont, NY (US); Liqiao Qin, Albany, NY (US)

(21) Appl. No.: 17/930,706

(22) Filed: Sep. 8, 2022

(51) Int. Cl. H01L 29/423; H01L 29/06; H01L 29/786

(52) U.S. Cl. CPC H01L 29/42392; H01L 29/0665; H01L 29/78696

(57) ABSTRACT

A semiconductor device, such as an integrated circuit, microprocessor, wafer, or the like, includes a first gate all around field effect transistor (GAA FET) and second GAA FET within the same region type (e.g., p-type region or n-type region, etc.) with relatively heterogenous channels within the same region. The first GAA FET includes a plurality of first channels of a first channel material (e.g., SiGeₓ cladded channels). A second GAA FET includes a plurality of second channels of a second channel material (e.g., SiGe_{y} cladded channels, Si channels, or the like). The GAA FETs may have different channel structures, such as relatively different channel lengths. The heterogenous channels may provide improved GAA FET device performance by allowing an ability to tune or adjust channel mobility of GAA FETs in similar region types in different locations or when utilized in different applications.

### BACKGROUND

Various embodiments of the present application generally relate to semiconductor device fabrication operations and resulting devices. More specifically the various embodiments relate to gate all around transistors that includes relatively heterogeneous channels.

Conventional semiconductor devices, such as integrated circuits (ICs), or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes.

One particularly radical technology change entailed re-designing the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanowire(s), sheet(s) that are isolated from the substrate. In the GAA FET the respective channel surfaces that are not in contact with the source and drain are in contact with and surrounded by the gate.

In pFET regions of the GAA FET, channel mobility may be improved by incorporating strained or unstrained Silicon Germanium (SiGe) channels. However, in certain implementations, not all pFET GAA FETs within the semiconductor device benefit from SiGe channels. Therefore, embodiments of the present disclosure provide fabrication techniques to form a semiconductor device that includes heterogenous channels within similar regions (e.g., pFET regions, etc.).

### SUMMARY

In an embodiment of the present disclosure, a semiconductor device is presented. The semiconductor device includes a first gate all around field effect transistor (GAA FET) within a first region of a first type and a second GAA FET within a second region of the first type. The first GAA FET includes a plurality of first nanostructure channels of a first channel material and the second GAA FET includes a plurality of second nanostructure channels of a second channel material.

The first region may be a p-type region and the second region may also be a p-type region. The first channel material may be Silicon Germanium with a first Ge percentage (SiGeₓ) and wherein the second channel material is Silicon Germanium with a second Ge percentage (SiGe_{y}). The plurality of second nanostructure channels may each have a longer channel length relative to the plurality of first nanostructure channels.

The first GAA FET may further include a first portion of nanolayer channel between each of the plurality of first nanostructure channels and a first source and drain. Similarly, the second GAA FET may further include a second portion of nanolayer channel between each of the plurality of second nanostructure channels and a second source and drain.

In an embodiment of the present disclosure, another semiconductor device is presented. The semiconductor device includes a first gate all around field effect transistor (GAA FET) within a first p-type region and a second GAA FET within a second p-type region. The first GAA FET includes a plurality of Silicon Germanium (SiGe) nanostructure channels and the second GAA FET includes a plurality of Silicon (Si) nanostructure channels.

The plurality of Silicon nanostructure channels may each have a same or longer channel length relative to the plurality of SiGe nanostructure channels. The first GAA FET may further include a Si portion of nanolayer channel between each of the plurality of SiGe nanostructure channels and a first source and drain. Each of the plurality of Si nanostructure channels may directly contact a second source and drain.

The semiconductor device may further include a third GAA FET within a n-type region with one or more Silicon nanostructure channels. The one or more Silicon nanostructure channels may each have a same or different channel length relative to the plurality of SiGe nanostructure channels.

In another embodiment of the disclosure, a semiconductor device fabrication method is presented. The method includes forming a first gate all around field effect transistor (GAA FET) within a first region of a first type and forming a second GAA FET within a second region of the first type. The first GAA FET includes a plurality of first nanostructure channels of a first channel material and the second GAA FET comprising a plurality of second nanostructure channels of a second channel material.

The relatively different or heterogenous nanostructure channels within the GAA FETs within similar region types may provide improved GAA FET device performance by allowing an ability to tune or adjust channel mobility of GAA FETs in similar region types but in different locations, when the GAA FETs are utilized in different applications, and/or when the GAA FETs have relatively different geometries, such as channel lengths.

The relatively different or heterogenous nanostructure channels within the GAA FETs within similar region types may further provide a technique to change or adjust GAA FETs threshold voltage depending on material choices of the nanostructure channels therein. Further, when the first GAA FET and second GAA FET have relatively different geometries or are utilized with different performance requirements, such as the second GAA FET having relatively longer nanostructure channels, the second GAA FET is a relatively higher voltage GAA FET, is a lesser performance or non-critical GAA FET, or the like, it may be desirable for the first GAA FET and second GAA FET to have relatively different channel materials therein. For example, Silicon nanostructure channels may be desired for a second GAA FET in p-type regions, due to a lower risk of defectivity and decreased integration complexity, while SiGe nanostructure channels may be desired for the first GAA FET in p-type regions, due to relatively improved electron mobility therein.

These and other embodiments, features, aspects, and advantages will become better understood with reference to the following description, appended claims, and accompanying drawings.

### BRIEF DESCRIPTION OF THE DRAWINGS

FIG. 1 through FIG. 8 depicts respective cross-sectional views of a semiconductor device that includes gate all around transistors shown after sequential fabrication operation(s), in accordance with one or more embodiments of the disclosure.

FIG. 9 through FIG. 14 depicts respective cross-sectional views of a semiconductor device that includes gate all around transistors with heterogeneous channels shown after sequential fabrication operation(s), in accordance with one or more embodiments of the disclosure.

FIG. 15 is a flow diagram illustrating a semiconductor device fabrication method, in accordance with one or more embodiments of the disclosure.

FIG. 16 through FIG. 23 depicts respective cross-sectional views of a semiconductor device that includes gate all around transistors with heterogeneous channels shown after sequential fabrication operation(s), in accordance with one or more embodiments of the disclosure.

FIG. 24 is a flow diagram illustrating a semiconductor device fabrication method, in accordance with one or more embodiments of the disclosure.

FIG. 25 through FIG. 27 depicts respective cross-sectional views of a semiconductor device that includes gate all around transistors with heterogeneous channels shown after sequential fabrication operation(s), in accordance with one or more embodiments of the disclosure.

FIG. 28 is a flow diagram illustrating a semiconductor device fabrication method, in accordance with one or more embodiments of the disclosure.

### DETAILED DESCRIPTION

Embodiments of the disclosure recognize that not all GAA FETs or other devices within similar regions of the semiconductor device or across the semiconductor device benefit from the same homogenous channel type or material. As such, the present disclosure provides a fabrication method to form a plurality of GAA FETs or other devices that include heterogenous channels within similar regions or across the semiconductor device. The method includes forming a first GAA FET that includes a plurality of first channels of a first channel material. The method further includes forming a second GAA FET that includes a plurality of second channels of a second channel material. The method may further include forming a third GAA FET that includes a plurality of third channels of a third channel material. For example, a first p-type GAA FET that includes SiGeₓ channels is formed, a second p-type GAA FET that includes SiGe_{y} channels is formed, and/or a third p-type GAA FET that includes Si channels is formed.

The similar region GAA FETs with heterogenous channels may have different structures, such as relatively different channel lengths. For example, a first p-type GAA FET may include SiGe short channels and a second p-type GAA FET may include Si long channels, where the length of the long channels is greater than the length of the short channels.

The embodiments of the present disclosure may provide improved GAA FET device performance by improving p-type GAA FET channel mobility, by reducing channel trim defects and process complexity on long channel GAA FETs, and/or by providing GAA FET design flexibility that allows for GAA FETs with different channels according to design or semiconductor device requirements.

Although this detailed description includes examples of how embodiments of the disclosure can be implemented to form an exemplary semiconductor device with various GAA FETs, implementation of the teachings recited herein are not limited to a particular type of GAA FET structure or combination of materials depicted or described. Rather, embodiments of the present disclosure are capable of being implemented in conjunction with other transistor types or materials, now known or later developed, wherein it is desirable to provide for transistors with heterogenous gates within p-type or n-type regions.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. Various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a semiconductor device that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to a description of technologies that are more specifically relevant to the present disclosure, transistors are semiconductor devices commonly found in a wide variety of ICs. Typical semiconductor devices are formed using active regions of a wafer. The active regions are defined by isolation regions used to separate and electrically isolate adjacent semiconductor devices. For example, in an IC having a plurality of GAA FETs, each GAA FET has a source and a drain that are formed in an active region of a semiconductor layer by implanting n-type or p-type impurities in the respective source and the drain material. Disposed between the source and the drain is a channel (or body) region. Disposed around the channel is the gate. The gate and the channel are spaced apart by a dielectric layer.

GAA FETs may be fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

The wafer footprint of a GAA FET is related to the electrical conductivity of the channel material. If the channel material has a relatively high conductivity, the GAA FET can be made with a correspondingly smaller wafer footprint. A known method of increasing channel conductivity and decreasing GAA FET size is to form the channel as a nanostructure, such as a nanowire or nanosheet. These GAA FETs provide a relatively small FET footprint by forming the channel as a series of vertical nanostructures.

In a known GAA configuration, a nanostructure-based FET includes a source region, a drain region, and stacked nanostructure channels between the source and drain regions. A gate surrounds the stacked nanostructure channels and regulates electron flow through the nanostructure channels between the source and drain regions. GAA FETs may be fabricated by forming alternating layers of channel nanostructure and sacrificial nanostructure layers. The sacrificial nanostructure layers are released from the channel nanostructures before the GAA FET device is finalized. For n-type GAA FETs, the channel nanostructure layers may be silicon (Si) and the sacrificial nanostructure layers may be silicon germanium (SiGe). For p-type GAA FETs, in some implementations, the channel nanostructure layers may be SiGe and the sacrificial nanostructure layers may be Si and in other implementations, the channel nanostructure may be Si, and the sacrificial nanostructure can be SiGe.

In some implementations, the channel nanostructure layers may initially be Si and can be converted to SiGe or other material, after sacrificial nanostructure layers are removed.

Forming the GAA nanostructures from alternating layers of channel nanostructure layers formed from a first type of semiconductor material (e.g., Si for n-type FETs, and SiGe for p-type FETs) and sacrificial nanostructure layers formed from a second type of semiconductor material (e.g., SiGe for n-type FETs, and Si for p-type FETs) may provide for superior channel electrostatics control, which is beneficial for continuously scaling of CMOS technology. The use of different channel materials for p-type GAA FETs vs. n-type GAA FETs is typically to improve channel mobility, and resultant overall device performance. Further, the use of different channel materials for GAA FETs in a first p-type or n-type region vs. GAA FETs in a second and same p-type or n-type region may further improve channel mobility and structural integrity, where desired, and may therefore also improve resultant overall device performance.

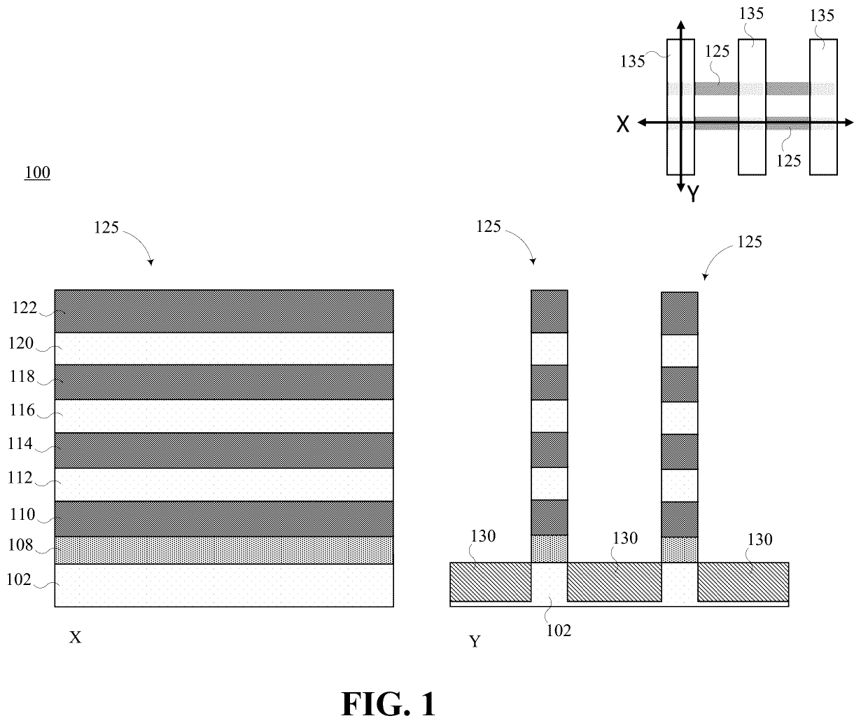

Turning now to a more detailed description of fabrication operations and resulting structures according to embodiments of the disclosure, FIGS. 1-8 depict a semiconductor device 100 after various fabrication operations. For ease of illustration, the fabrication operations depicted in FIGS. 1-8 will be described in the context of forming one or more GAA FETs. The fabrication operations described herein apply equally to the fabrication of any number and/or logical positioning of various FET types.

Although the cross-sectional structural diagrams depicted in the drawings are two-dimensional, it is understood that the diagrams depicted represent three-dimensional devices. The top-down reference diagram shown in FIG. 1 provides a reference point for various cross-sectional views (X-view, Y-view) shown in FIGS. 1-8. The X-view is a side cross-sectional view taken along a channel stack 125 across three gates 135, the Y-view is another side cross-sectional view taken along a gate 135 across two channel stacks 125. For clarity, gate 135 is depicted as a generic gate or gate structure and may be, for example, a sacrificial gate or sacrificial gate structure, a replacement gate conductor or replacement gate structure, or the like.

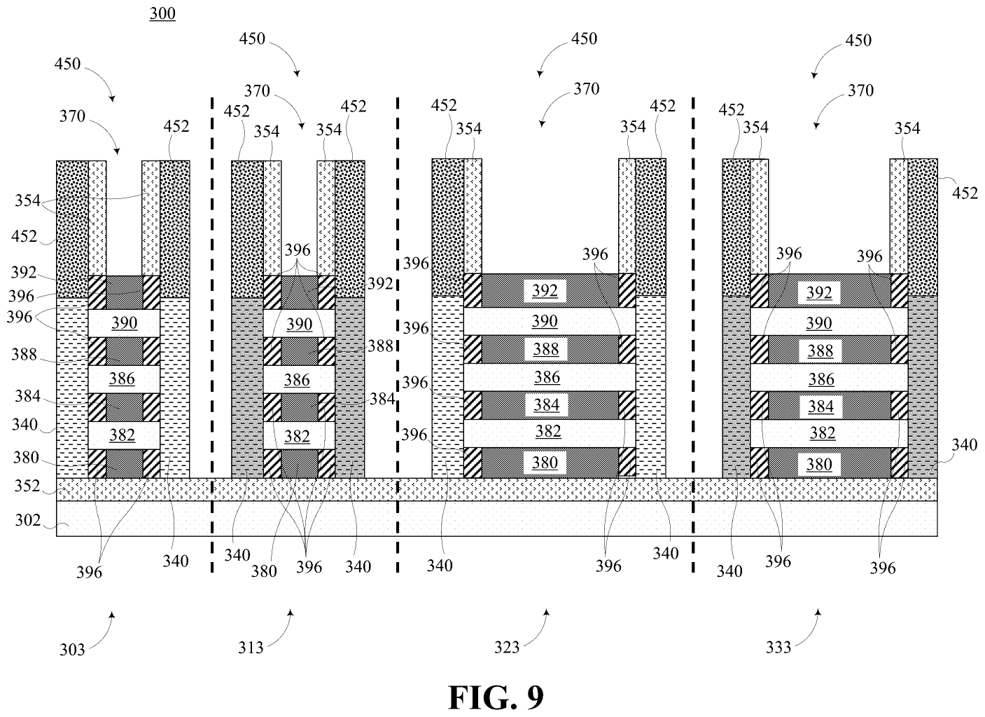

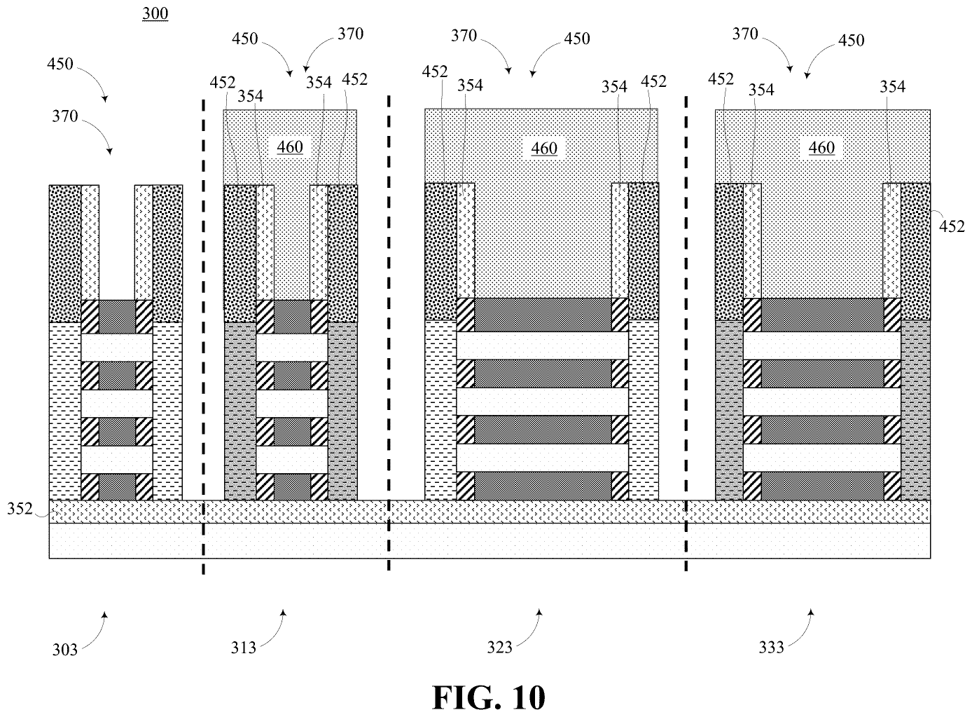

FIGS. 9-14 depict a semiconductor device 300 after various fabrication operations. For ease of illustration, the fabrication operations depicted in FIGS. 10-14 will be described in the context of forming a first GAA FET that includes a short channel of a first channel material in a p-type region, forming a second GAA FET that includes a short channel of a second channel material in a n-type region, forming a third GAA FET that includes a long channel of the second channel material in a p-type region, and forming a fourth GAA FET that includes a long channel of the second channel material in a n-type region. The fabrication operations described herein apply equally to the fabrication of any number and/or logical positioning of various FET types. The cross section of the structure of FIGS. 9-14 is like the X-view cross-sectional view described above.

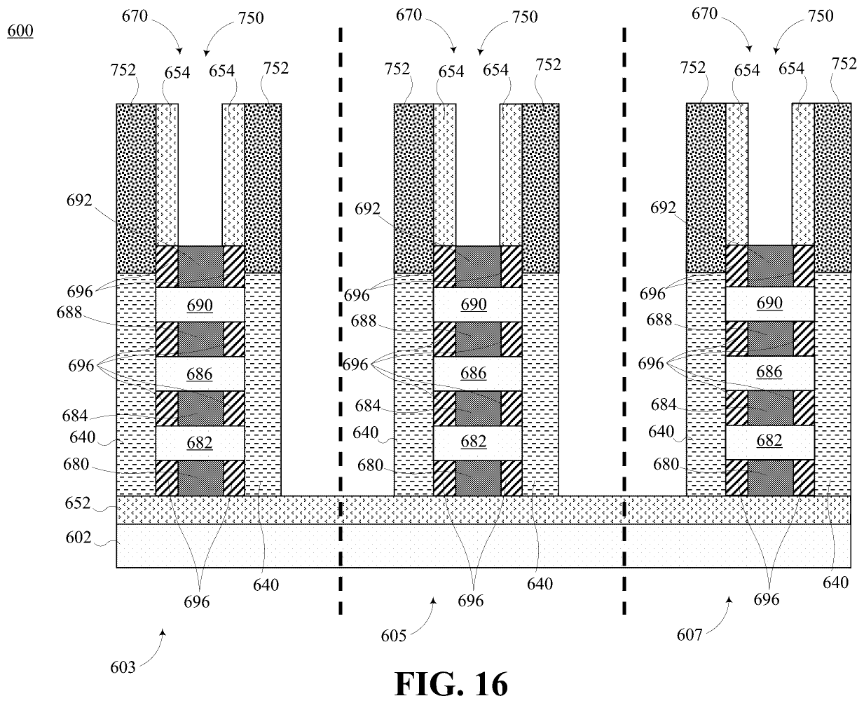

FIGS. 16-23 depict a semiconductor device 600 after various fabrication operations. For ease of illustration, the fabrication operations depicted in FIGS. 16-23 will be described in the context of forming a first GAA FET that includes a channel of a first channel material in a particular region type (e.g., p-type region), forming a second GAA FET that includes a channel of a second channel material in the same particular region type, and/or forming a third GAA FET that includes a channel of a third channel material in the same particular region type. The fabrication operations described herein apply equally to the fabrication of any number and/or logical positioning of various FET types. The cross section of the structure of FIGS. 16-23 is like the X-view cross-sectional view described above.

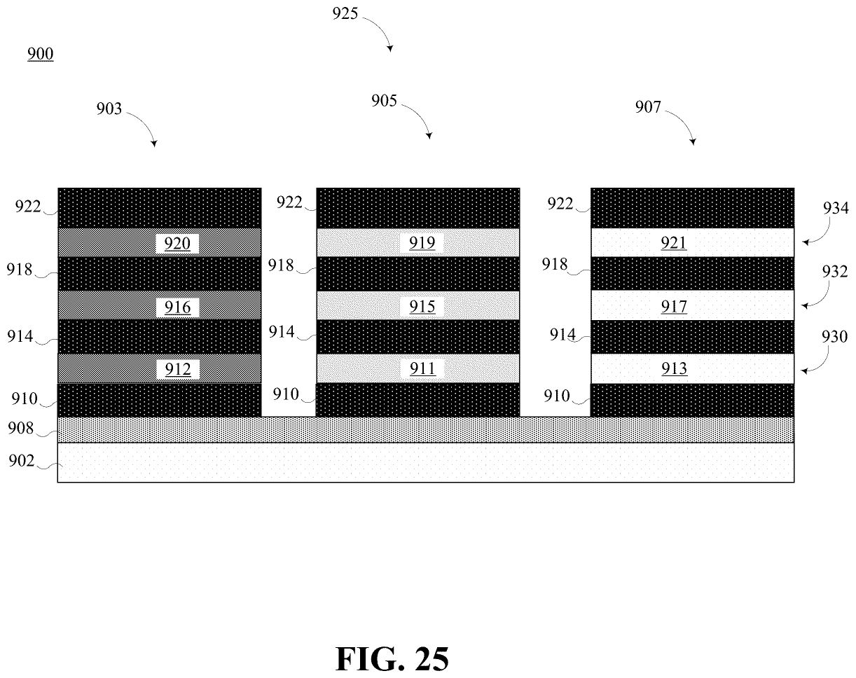

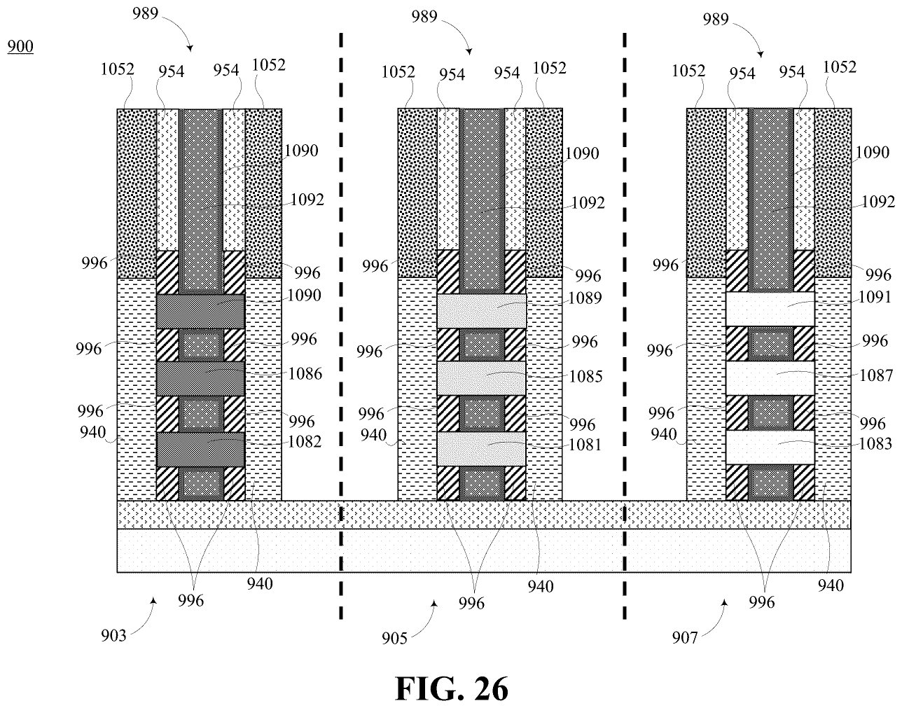

FIG. 25 through FIG. 27 depict a semiconductor device 900 after various fabrication operations. For ease of illustration, the fabrication operations depicted in FIG. 25 through FIG. 27 will be described in the context of forming a first GAA FET that includes a channel of a first channel material in a particular region type (e.g., p-type region), forming a second GAA FET that includes a channel of a second channel material in the same particular region type, and/or forming a third GAA FET that includes a channel of a third channel material in the same particular region type. The fabrication operations described herein apply equally to the fabrication of any number and/or logical positioning of various FET types. The cross section of the structure of FIG. 25 through FIG. 27 is like the X-view cross-sectional view described above. For clarity, the semiconductor device 900 depicted in FIG. 26 includes the first GAA FET with a short channel of a first channel material, a second GAA FET with a short channel of a second channel material, and/or the third GAA FET with a short channel of a third channel material all located in the same region type, but not necessarily the same region location.

For clarity, the term “same region type” or the like is defined herein to be regions of a semiconductor device that share the same semiconductor impurities within the transistors formed therein to form the same type of transistor (e.g., p-type regions share the same or similar trivalent impurities in the appropriate transistor structure(s) to form p-type transistors and n-type regions share the same or similar pentavalent impurities in the appropriate transistor structure(s) to form n-type transistors) but need not be in the same region location. For example, the three GAA FETs that are in the same region type may all be p-type GAA FETs and may be located within the same p-type region location and/or different p-type region locations.

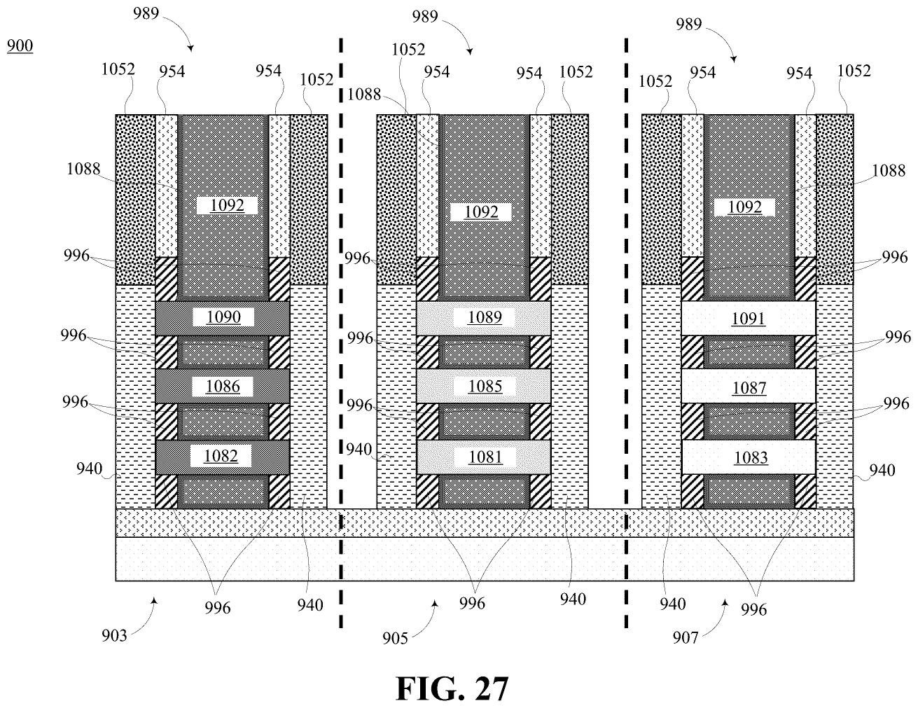

Similarly, the semiconductor device 900 depicted in FIG. 27 includes the first GAA FET with a long channel of a first channel material, a second GAA FET with a long channel of a second channel material, and/or the third GAA FET with a long channel of a third channel material all located in the same region type, but not necessarily the same region location.

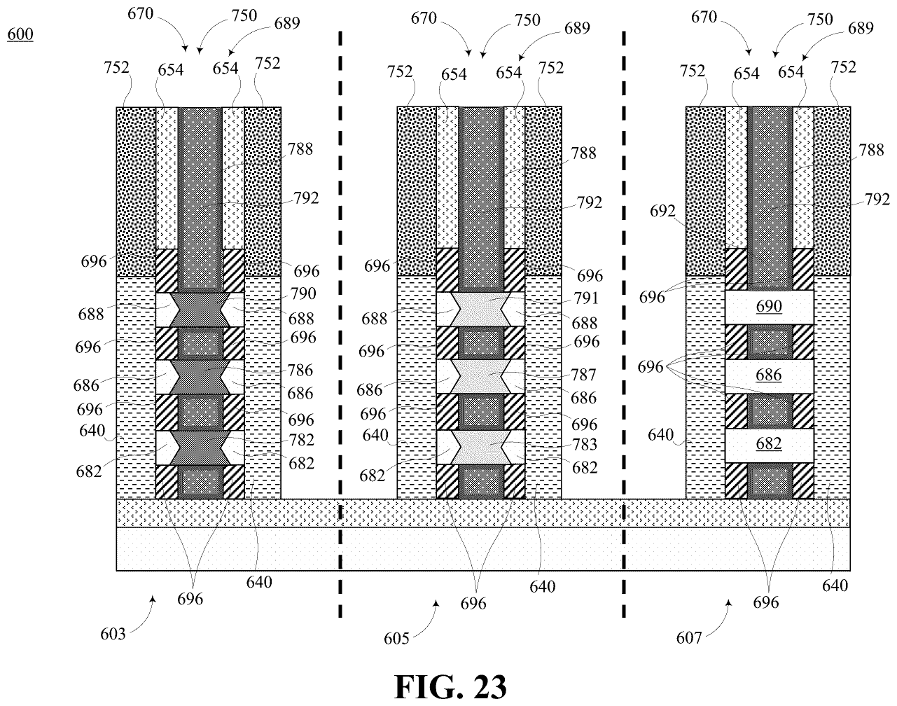

For clarity, the embodiments of the disclosure describe multiple techniques to form GAA FETs with heterogenous channels. For instance, the GAA FETs associated with FIG. 9 through FIG. 23 depict a second material last process where the second material is formed after an initial channel of the first material is formed whereas the GAA FETs associated with FIG. 23-FIG. 27 depict a second material first process where the channels of first material and different channels of the second material are simultaneously formed, or the like. Other techniques now or later developed may incorporate at least some of the embodiments of the disclosure to form GAA FETs with heterogenous channels as at least structurally contemplated herein.

FIG. 1 depicts cross-sectional views of the semiconductor device 100 after initial fabrication operations in accordance with embodiments of the present disclosure. In the present fabrication stage, one or more nanolayer stacks 125 are formed upon a substrate 102. Further in the present fabrication stage, shallow trench isolation (STI) region(s) 130 may be formed upon the substrate 102 next to nanolayer stacks 125.

Non-limiting examples of suitable materials for the substrate 102 include Si (silicon), strained Si, SiC (silicon carbide), Ge (germanium), SiGe (silicon germanium), SiGe:C (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof. Other non-limiting examples of semiconductor materials include III-V materials, for example, indium phosphide (InP), gallium arsenide (GaAs), aluminum arsenide (AlAs), or any combination thereof. The III-V materials can include at least one “III element,” such as aluminum (Al), boron (B), gallium (Ga), indium (In), and at least one “V element,” such as nitrogen (N), phosphorous (P), arsenic (As), antimony (Sb). The substrate 102 can be a bulk semiconductor material that includes Si.

A bottom sacrificial layer 108 may be formed upon substrate 102. Subsequently, alternating nanostructure layers may be formed upon the bottom sacrificial layer 108. The bottom sacrificial layer 108 may be initially formed over substrate 102. The bottom sacrificial layer 108 may comprise an epitaxial SiGe layer with high Ge %, ranging from 50% to 70%. In some embodiments of the invention, the bottom sacrificial layer 108 is SiGe having a Ge percentage that is sufficiently different from the Ge percentage in the sacrificial nanolayers, such that the bottom sacrificial layer 108 can be selectively removed without also removing the SiGe sacrificial nanolayers. The bottom sacrificial layer 108 can have a thickness of, for example, from about 4 to about 15 nm.

The nanolayer stack 125 may include portions formed of an alternating series of sacrificial nanolayers, such as SiGe sacrificial nanolayers, and portions of nanolayers, such as Si nanolayers. The sacrificial SiGe nanolayers could have lower Ge % ranging from 20% to 45%. Sacrificial portions 110, 114, 118, and 122 of each nanolayer stack 125 may be formed from an associated sacrificial nanolayer and nanostructure portions 112, 116, and 120 of each nanolayer stack 125 may be formed from an associated nanolayer.

In accordance with embodiments of the disclosure, the bottom sacrificial layer may be epitaxially grown from the substrate 102 and the alternating nanolayers may be formed by epitaxially growing one layer and then the next until the desired number and desired thicknesses of the layers are achieved. Any number of alternating layers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In some embodiments of the invention, the nanolayers are formed from silicon (Si) and can include, for example, monocrystalline Si. The nanolayers can have a thickness of, for example, from about 4 to about 12 nm. In embodiments where the sacrificial nanolayers include SiGe, the sacrificial nanolayers can have a thickness of, for example, from about 4 to about 12 nm. Subsequently, a mask layer (not shown) may be formed upon the top of the uppermost sacrificial nanolayer.

At the present fabrication stage, each nanolayer stack 125 may include bottom sacrificial portion 108, sacrificial nanolayer portion 110, nanostructure channel 112, sacrificial nanolayer portion 114, nanostructure channel 116, sacrificial nanolayer portion 118, nanostructure channel 120, and sacrificial nanolayer portion 122. The nanolayer stacks 125 may be formed by patterning the associated layers, or portions thereof. Subsequently, STI regions 130 may be formed over the substrate 102 and adjacent to the one or more nanolayer stacks 125. In the embodiment depicted, a top surface of one or more STI regions 130 may be coplanar with a bottom surface of bottom sacrificial portion(s) 108 of one or more nanolayer stacks 125.

The one or more nanolayer stacks 125 may be patterned by removing respective undesired portion(s) or section(s) of the aforementioned layers while retaining respective desired portions. The removal of undesired portions of the bottom sacrificial layer and the alternating sacrificial nanolayers and nanolayers can be accomplished using, for example, conventional lithography and etch process. The removal of such undesired portions may further remove undesired portions of substrate 102, as depicted. Desired portions of bottom sacrificial layer and the alternating sacrificial nanolayers and nanolayers may be retained, thereby forming the one or more nanolayer stacks 125.

STI regions 130 may be formed by depositing STI dielectric material upon the substrate 102 and adjacent to the nanolayer stacks 125, followed by STI dielectric material etch back, recess, or the like. STI regions 130 may electrically isolate components or features of neighboring GAA FETs, or the like.

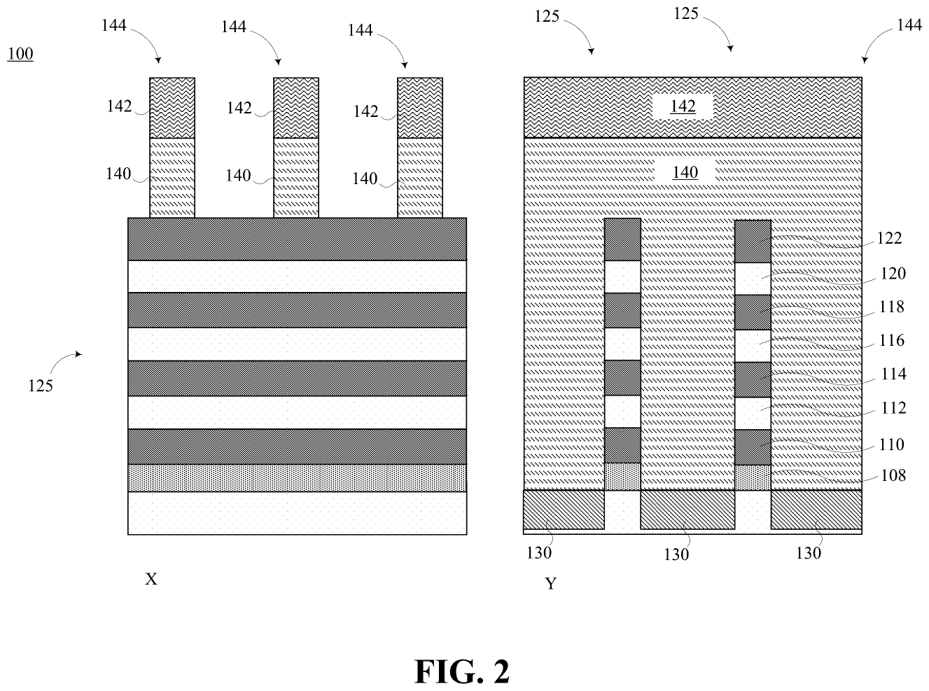

FIG. 2 depicts cross-sectional views of semiconductor device 100 shown after exemplary fabrication operation(s), in accordance with one or more embodiments. In the depicted fabrication stage one or more sacrificial gate structures 144 are formed upon and around the one or more nanolayer stacks 125 and upon STI regions 130. Sacrificial gate structure 144 may include a sacrificial gate liner (not shown), a sacrificial gate 140, and a sacrificial gate cap 142.

The sacrificial gate structure 144 may be formed by forming a sacrificial gate liner layer (e.g., a dielectric, oxide, or the like) upon STI regions 130 and upon and around nanolayer stacks 125. For instance, the sacrificial gate liner layer may be deposited upon the upper surface of STI regions 130, sidewalls of bottom sacrificial portion 108, sidewalls of sacrificial nanolayer portion 110, sidewalls of nanostructure channel 112, sidewalls of sacrificial nanolayer portion 114, sidewalls of nanostructure channel 116, sidewalls of sacrificial nanolayer portion 118, sidewalls of nanostructure channel 120, and sidewalls and upper surface of sacrificial nanolayer portion 122.

The sacrificial gate structure 144 may further be formed by subsequently forming a sacrificial gate layer (e.g., amorphous silicon, or the like) upon the sacrificial gate liner. The thickness of the sacrificial gate layer may be greater than the height of the one or more nanolayer stacks 125.

The sacrificial gate structure 144 may further be formed by subsequently forming a gate cap layer upon the sacrificial gate layer. The gate cap layer may be formed by depositing a mask material, such as a hard mask material. The gate cap layer may be composed of one or more layers masking materials to protect the sacrificial gate layer and/or other underlying materials during subsequent processing of device 100. The gate cap layer can be formed of known gate mask materials such as silicon nitride, silicon oxide, combinations thereof, or the like.

The gate cap layer, sacrificial gate layer, and sacrificial gate liner may be patterned using conventional lithography and etch process to remove undesired portions and retain desired portion(s), respectively. The retained desired portion(s) of the gate cap layer, sacrificial gate layer, and sacrificial gate liner may form the sacrificial gate liner (not shown), the sacrificial gate 140, and the sacrificial gate cap 142, respectively, of each of the one or more sacrificial gate structures 144.

Each sacrificial gate structure 144 can be formed on targeted regions or areas of semiconductor device 100 to define the length of one or more GAA FETs, one or more GAA FET channels, or the like, and to provide sacrificial material for yielding targeted GAA FET structure(s) in subsequent processing. According to an example, each sacrificial gate structure 144 can have a height of between approximately 50 nm and approximately 200 nm, and a length of between approximately 10 nm and approximately 200 nm.

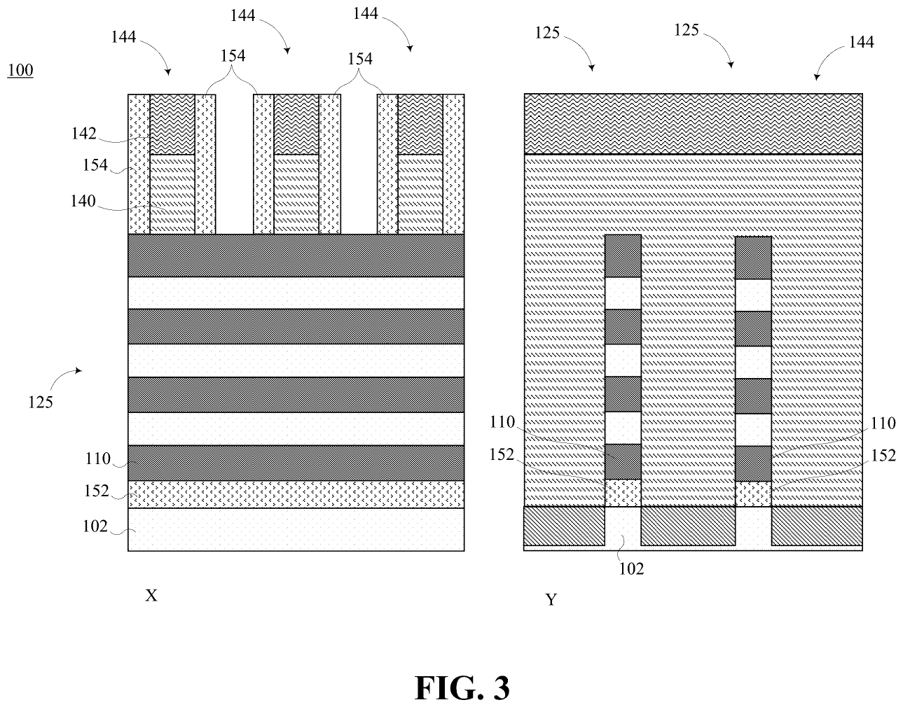

FIG. 3 depicts cross-sectional views of semiconductor device 100 shown after exemplary fabrication operation(s), in accordance with one or more embodiments. In the depicted fabrication stage, bottom sacrificial portion 108 may be selectively removed, BDI region 152 may be formed in place thereof, and one or more gate spacers 154 may be formed.

Bottom sacrificial portion 108 may be selectively removed and may resultantly form an associated BDI cavity between substrate 102 and sacrificial nanolayer portion 110, respectively. In place of the removed bottom sacrificial portion 108, a bottom dielectric isolation (BDI) region 152 may be formed between substrate 102 and sacrificial nanolayer portion 110 within each nanolayer stack 125.

Further in the depicted fabrication stage, a gate spacer 154 may formed around each of the one or more sacrificial gate structures 144. Each gate spacer 154 may further be formed upon at least a portion of the sidewalls of the one or more nanolayer stacks 125 and upon the top surface of a portion of the STI regions 130.

BDI region 152 and gate spacers 154 may be simultaneously formed by a conformal deposition of a dielectric material, such as silicon nitride, SiBCN, SiNC, SiN, SiCO, SiNOC, or a combination thereof, or the like, within the BDI cavitie(s) and upon STI regions 130 and around each of the one or more sacrificial gate structures 144. Undesired portion(s) of the dielectric material may be removed by etching or other subtractive material removal process. Desired portion(s) of the dielectric material may be retained within the BDI cavity and may form BDI region(s) 152. Further additional desired portion(s) of the dielectric material may be retained upon the top surface of STI regions 130 adjacent to and upon the sidewalls of the sacrificial gate structure 144 and around the one or more nanolayer stacks 125.

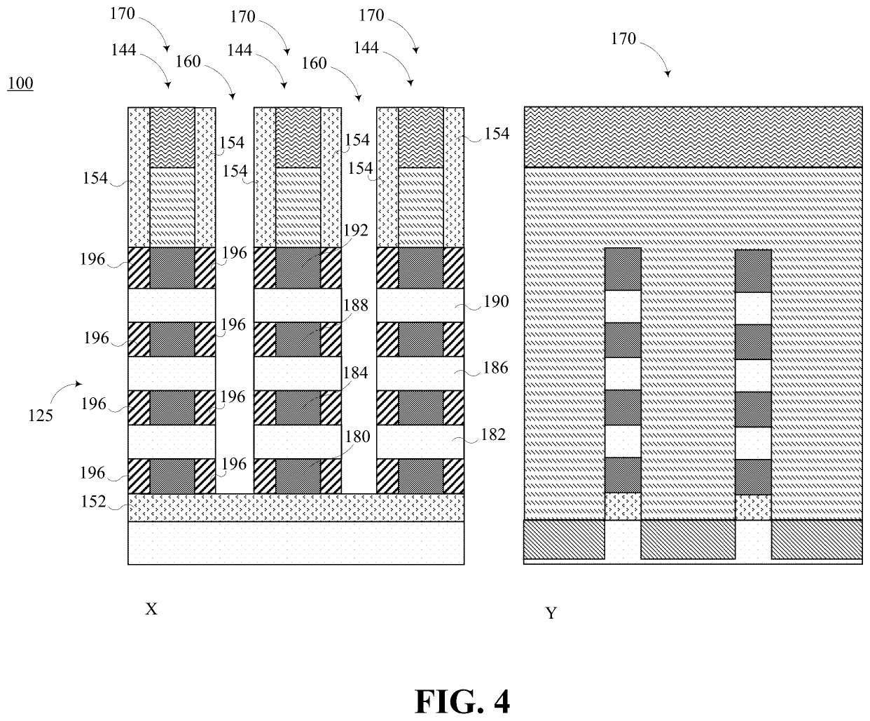

FIG. 4 depicts cross-sectional views of semiconductor device 100 shown after exemplary fabrication operation(s), in accordance with one or more embodiments. In the depicted fabrication stage, one or more source/drain (S/D) recesses 160 and one or more nanostructure stacks 170 are formed.

The one or more S/D recesses 160 and the one or more nanostructure stacks 170 may be formed by recessing or otherwise removing at least one respective portion of the one or more nanolayer stacks 125 that are not protected by sacrificial gate structure 144 and/or gate spacer 154. For example, unprotected and/or undesired portions of each nanolayer stack 125 may be etched or otherwise removed. The etch may utilize the top surface of BDI 152 as an etch stop. The retained one or more portions of nanolayer stack 125 may effectively form nanostructure stacks 170.

At the present fabrication stage, nanostructure stack 170 may include a sacrificial nanolayer portion 180 formed from the sacrificial nanolayer portion 110, a nanostructure channel 182 formed from nanostructure channel 112, a sacrificial nanolayer portion 184 formed from the sacrificial nanolayer portion 114, a nanostructure channel 186 formed from nanostructure channel 116, a sacrificial nanolayer portion 188 formed from the sacrificial nanolayer portion 118, a nanostructure channel 190 formed from nanostructure channel 120, and a sacrificial nanolayer portion 192 formed from the sacrificial nanolayer portion 122.

The one or more nanostructure stacks 170 may be further modified or fabricated by selectively recessing the length or otherwise laterally indenting the sacrificial nanolayer portions 180, 184, 188, 192, etc. This lateral recessing of sacrificial nanolayer portions 180, 184, 188, 192 can be provided, e.g., vapor-phase process which leaves other structures (e.g., substrate 102, BDI 152, gate spacer 154, nanostructure channels 182, 186, 190, etc.) substantially intact.

Inner spacers 196 may be formed within the indentations or lateral recess of the sacrificial nanolayer portions 180, 184, 188, 192. Inner spacers 196 may be formed by depositing an electrically insulative material, such as a dielectric, to pinch off the previously formed recesses to yield an inner spacer 196 positioned therewithin, (e.g., above and below each nanostructure channel 182, 186, 190 within the nanosheet stack 170). For example, an inner spacer 196 can be formed upon the sidewall of sacrificial nanolayer portion 180 and between BDI 152 and nanostructure channel 182, an inner spacer 196 can be formed upon the sidewall of sacrificial nanolayer portion 184 and between nanostructure channel 182 and nanostructure channel 186, an inner spacer 196 can be formed upon the sidewall of sacrificial nanolayer portion 188 and between nanostructure channel 186 and nanostructure channel 190, and an inner spacer 196 can be formed upon the sidewall of sacrificial nanolayer portion 192 and between nanostructure channel 190 and gate spacer 154. At the present fabrication stage, nanostructure stack 170 may further include spacers 196.

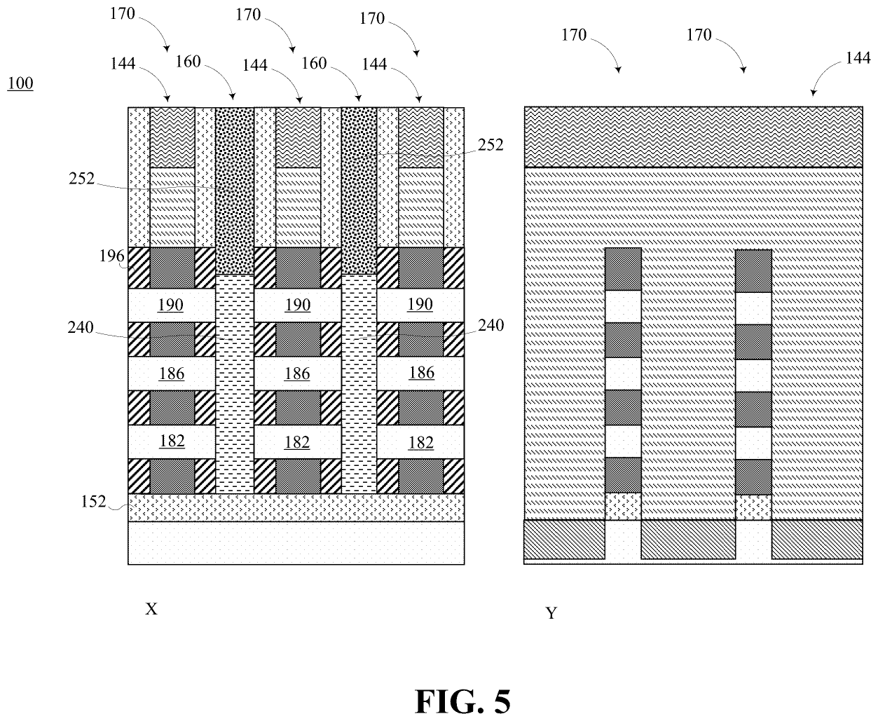

FIG. 5 depicts cross-sectional views of semiconductor device 100 shown after exemplary fabrication operation(s), in accordance with one or more embodiments. In the depicted fabrication stage, a S/D region 240 is formed in the one or more S/D recesses 160, respectively and a S/D cap 252 is formed on the one or more S/D regions 240, respectively.

S/D region 240 may be formed by epitaxially growing a source/drain epitaxial region within S/D recess 160, e.g., from exposed inner sidewalls within S/D recess 160. In some embodiments, the S/D region 240 is formed by in-situ doped epitaxial growth. In some embodiments, epitaxial growth and/or deposition processes may be selective to forming on semiconductor surfaces, and may not deposit material on dielectric surfaces, such as silicon dioxide or silicon nitride surfaces. In some embodiments, the S/D region 240 epitaxial growth may overgrow above the upper surface of semiconductor device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in S/D region 240 can be in the range of 1×10¹⁹ cm⁻³ to 2×10²¹ cm⁻³, or preferably between 2×10²⁰ cm⁻³ to 7×10²⁰ cm⁻³.

In certain implementations, S/D region 240 may be partially recessed such that an upper portion of the S/D region 240 are removed. For example, the upper portion of the one or more S/D regions 240 may be etched or otherwise removed. The etch may be timed or otherwise controlled to stop the removal of the one or more S/D regions 240 such that the top surface of the remaining one or more S/D regions 240 is above the upper surface of nanostructure channel 190. The partial removal of the upper portion of the S/D region 240 may at least partially reform S/D recess 160.

S/D cap 252 may be formed on the one or more S/D regions 240 within the partially reformed S/D recess 160, respectively. S/D cap 252 may be formed by depositing a dielectric material, such as silicon oxide, silicon nitride, SiBCN, SiNC, SiN, SiCO, SiNOC, or a combination thereof, or the like, within the partially reformed S/D recess 160 and upon S/D region 240. In an embodiment, S/D cap 252 may be formed to a thickness above the top surface of semiconductor device 100 and subsequently planarized by a chemical mechanical polish (CMP) or etched such that the top surface of S/D cap 252 is coplanar with a top surface of the sacrificial gate structure 144 and/or a top surface of gate spacer 152. S/D cap 252 may also be referred to herein as a S/D insulator.

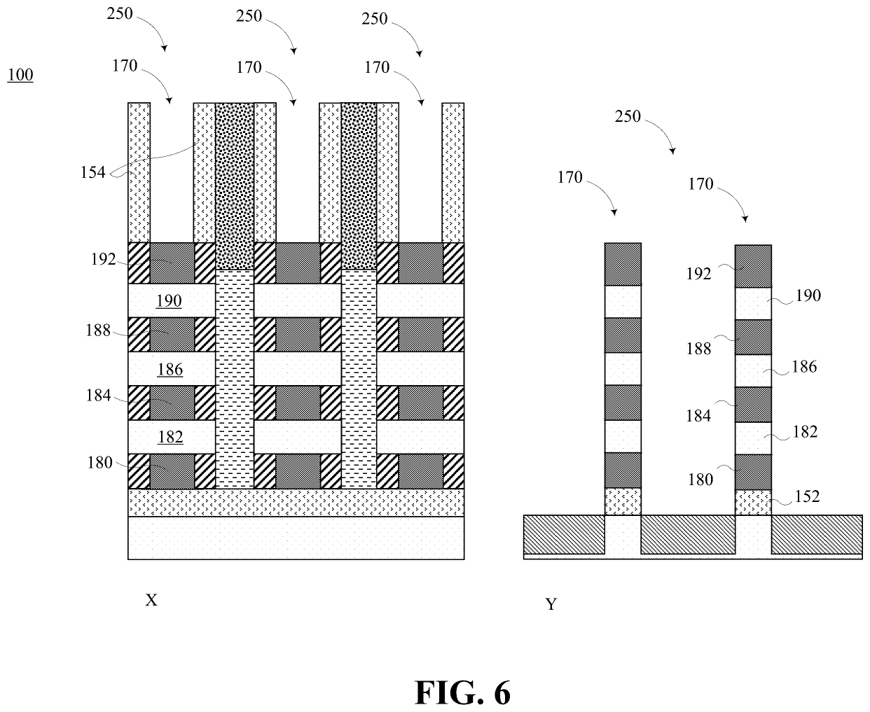

FIG. 6 depicts cross-sectional views of semiconductor device 100 shown after exemplary fabrication operation(s), in accordance with one or more embodiments. In the depicted fabrication stage, a gate opening 250 is formed.

Gate opening 250 may be formed by removing sacrificial gate structure 144 and, as depicted in the Y cross-sectional view, may expose at least respective sections of the upper surface of STI regions 130, respective sidewall surface sections of BDI 152, respective sidewall surface sections of sacrificial nanolayer portions 180, 184, and 188, and 192, and respective sidewall surface sections of nanolayer channels 182, 186, and 190.

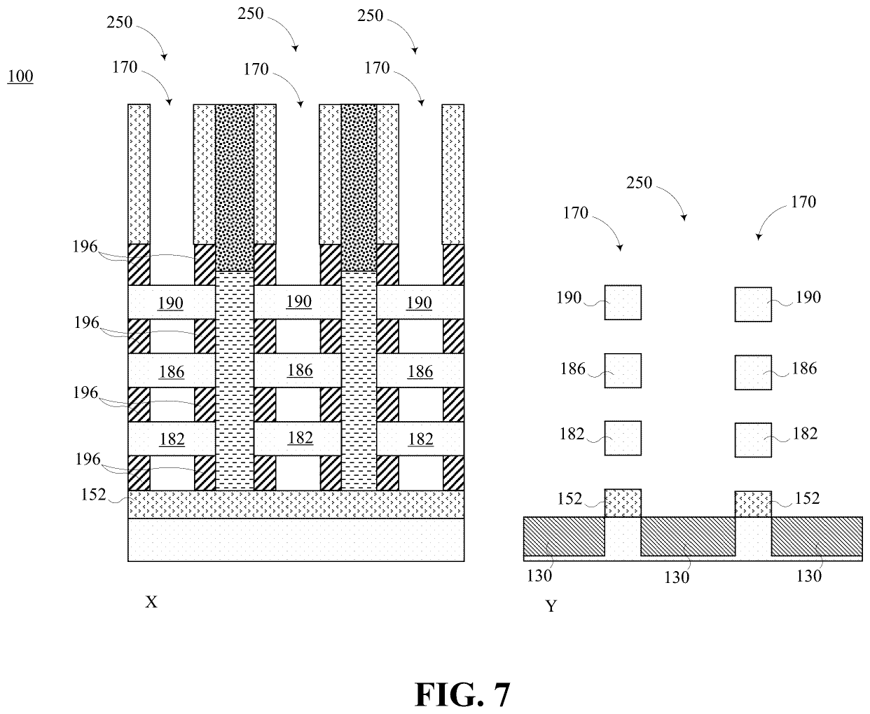

FIG. 7 depicts cross-sectional views of semiconductor device 100 shown after exemplary fabrication operation(s), in accordance with one or more embodiments. In the depicted fabrication stage, nanostructure stack 170 is modified by selectively removing the sacrificial nanolayer portions 180, 184, 188, and 192.

Various techniques may be utilized to process the nanostructure stack 170. For example, gate opening 250 may laterally, or otherwise, expose the nanostructure stack 170. Subsequently, the exposed sacrificial nanolayer portions 180, 184, 188, and 192 may be removed to expose the nanolayer channels 182, 186, and 190 within the nanostructure stack 170. As depicted in the X cross-section, upper and lower surfaces of nanolayer channels 182, 186, and 190 may be exposed inside or within neighboring inner spacers 196 associated with neighboring nanostructure stacks 170. As depicted in the Y cross-section, the perimeter of the nanolayer channels 182, 186, and 190 may be exposed inside or within neighboring inner spacers 196 associated with neighboring nanostructure stacks 170.

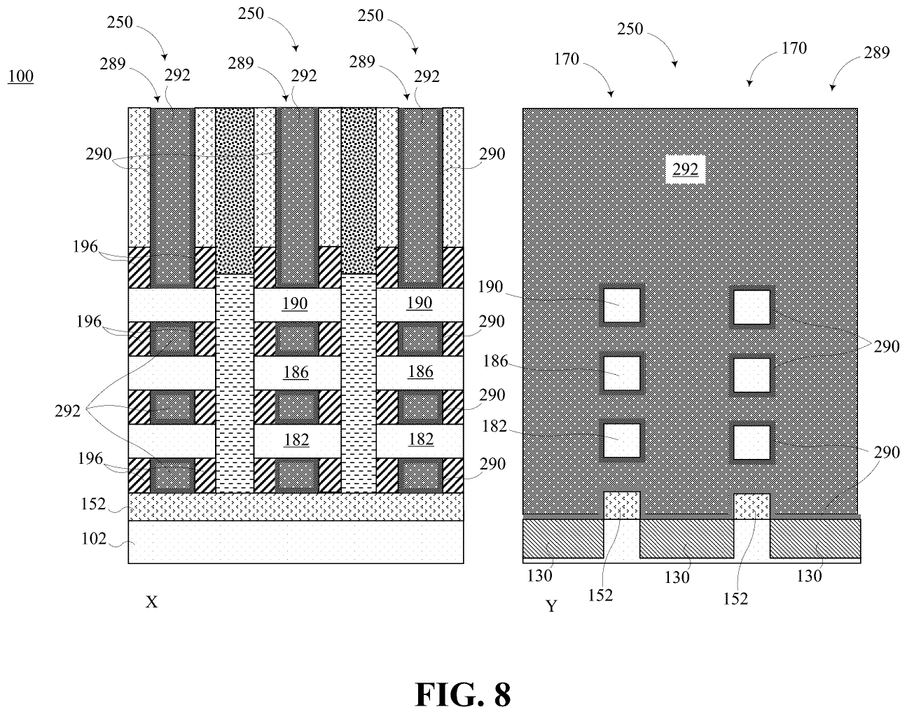

FIG. 8 depicts cross-sectional views of semiconductor device 100 shown after exemplary fabrication operation(s), in accordance with one or more embodiments. In the depicted fabrication stage, a replacement gate structure 289 is formed within gate opening 250 around nanolayer channels 182, 186, and 190.

Replacement gate structure 289 can include a gate dielectric 290 and gate conductor 292. Gate dielectric 290 can comprise any suitable dielectric material, including but not limited to silicon oxide, silicon nitride, silicon oxynitride, high-k materials, or any combination of these materials. The gate dielectric 290 can be formed by any suitable deposition process or the like. In some embodiments, the gate dielectric 290 has a thickness ranging from 1 nm to 5 nm, although less thickness and greater thickness are also conceived.

Gate conductor 292 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Gate conductor 292 may further comprise dopants that are incorporated during or after deposition. In some embodiments, the gate conductor 292 may further comprise a workfunction setting layer (not shown) between the gate dielectric 290 and gate conductor 292. The workfunction setting layer can be a workfunction metal (WFM). The gate conductor 292 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

Replacement gate structure 289 may be formed by initially forming the gate dielectric layer within gate opening 250 around the channels 182, 186, and 190, upon sidewalls of inner spacers 196, upon gate spacers 154, and upon the top surface of BDI 152. Replacement gate structure 289 may further be formed by subsequently forming a gate conductor layer upon the gate dielectric layer. For clarity, replacement gate structure 289 may be a wraparound gate structure, gate all around structure, since the gate conductor 292 wraps around the channels 182, 186, and 190, as is depicted in the Y cross-section.

The gate conductor layer and gate dielectric layer may be patterned using conventional lithography and etch process to remove undesired portions and retain desired portion(s), respectively. The retained desired portion(s) of the gate conductor layer and gate dielectric layer may form the gate dielectric layer 290 and gate conductor 292 of the replacement gate structure 292. The etch process, or another subtractive removal technique, may remove undesired portions of replacement gate structure 289, such that a top surface of replacement gate structure 289 is coplanar with the top surface of semiconductor device 100.

In some implementations, gate conductor 292 can be recessed below the top surface of semiconductor device 100 and a dielectric gate cap (not shown) can be formed upon the recessed gate conductor 292.

FIGS. 9-14 depict a semiconductor device 300 after various fabrication operations. For example, semiconductor device 300 depicted in FIG. 9 may have previously undergone similar fabrication operations to those depicted in FIGS. 1-5. As depicted in FIG. 9, semiconductor device 300 may include substrate 302, BDI 352, nanostructure stack 370, S/D 340, S/D cap 452, a sacrificial gate structure, and/or gate spacer 354. Nanostructure stack 370 may include sacrificial nanolayer portions 380, 384, 388, and 392. Nanostructure stack 370 may further include nanolayer channels 382, 386, and 390. Nanostructure stack 370 may further include inner spacers 396.

For clarity, substrate 302, BDI 352, nanostructure stack 370, S/D 340, S/D cap 452, sacrificial gate structure, and/or gate spacer 354 may be formed of similar material(s) and by similar fabrication techniques described with reference to associated features of semiconductor device 100.

Semiconductor device 300 may include a p-type GAA FET 303, a n-type GAA FET 313, a p-type GAA FET 323, and n-type GAA FET 333. Generally, the long channel GAA FETs include channels that have a greater channel length relative to associated channel lengths within the short channel GAA FETs. p-type GAA FET 303, n-type GAA FET 313, p-type GAA FET 323, and n-type GAA FET 333 may be formed upon the same substrate 302 and/or BDI 352. For clarity, p-type GAA FET 303 and p-type GAA FET 323 are formed in the same region type (i.e., p-type region) but may be formed in the same p-type region, or different p-type regions of semiconductor device 300, as depicted. Likewise, n-type GAA FET 313 and n-type GAA FET 333 are formed in the same region type (i.e., n-type region) but may be formed in the same n-type region, or different n-type regions of semiconductor device 300, as depicted. The p-type GAA FET 303 and n-type GAA FET 313 may include short channels and p-type GAA FET 323 and n-type GAA FET 333 may include long channels, where the length of the long channels are greater than the length of the short channels, as depicted.

The p-type GAA FET 303 and p-type GAA FET 323 include respective S/D 340 that include appropriate material(s), dopant(s), or the like. Similarly, n-type GAA FET 313 and n-type GAA FET 333 include respective S/D 340 that include appropriate material(s), dopant(s), or the like.

FIG. 9 depicts cross-sectional views of semiconductor device 300 shown after exemplary fabrication operation(s), in accordance with one or more embodiments. In the depicted fabrication stage, a gate opening 450 is formed.

Gate opening 450 may be formed by removing sacrificial gate structure and may expose at least respective sections of the upper surface of STI regions, respective sidewall surface sections of BDI 352, respective sidewall surface sections of sacrificial nanolayer portions 380, 384, 388, and 392, and respective sidewall surface sections of nanolayer channels 382, 386, and 390. In other words, gate opening 450 may expose the side surfaces of BDI 352, sacrificial nanolayer portions 380, 384, 388, and 392, and nanolayer channels 382, 386, and 390. Gate opening 450 may further expose the top surface of sacrificial nanolayer portion 392. Gate opening 450 may further expose at least an inner portion or inside facing portion of gate spacer 354.

FIG. 10 depicts cross-sectional views of semiconductor device 300 shown after exemplary fabrication operation(s), in accordance with one or more embodiments. In the depicted fabrication stage, mask 460 is formed over p-type GAA FET 323, n-type GAA FET 313, and/or n-type GAA FET 333.

Mask 460 may be a dielectric material, organic planarization material, or mask material, and may be formed by depositing a blanket mask material over p-type GAA FET 303, p-type GAA FET 323, n-type GAA FET 313, and/or n-type GAA FET 333. The mask material may be deposited upon respective S/D caps 452, upon respective gate spacers 354, upon and around respective nanostructure stacks 370, upon respective BDI 352, and/or upon respective STI regions. A portion of the mask material may be subsequently removed over p-type GAA FET 303, thereby re-exposing at least gate opening 450 and/or nanostructure stack 370 thereof.

Mask 460 may protect p-type GAA FET 323, n-type GAA FET 313, and/or n-type GAA FET 333 from subsequent channel processing of p-type GAA FET 303.

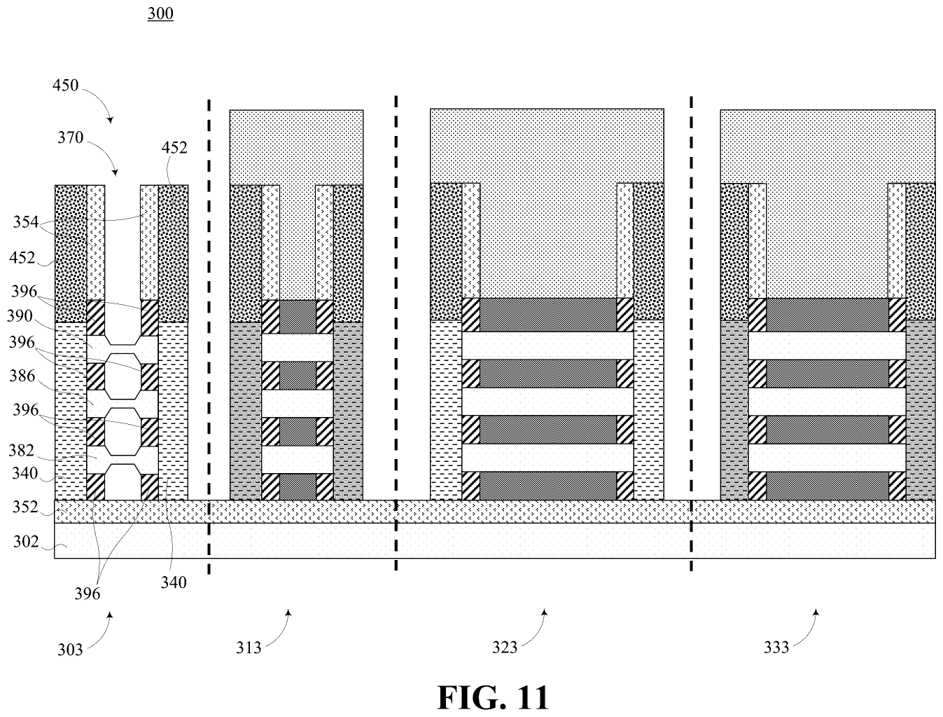

FIG. 11 depicts cross-sectional views of semiconductor device 300 shown after exemplary fabrication operation(s), in accordance with one or more embodiments. In the depicted fabrication stage, nanostructure stack 370 of p-type GAA FET 303 is processed by selectively removing the sacrificial nanolayer portions 380, 384, 388, and 392 and by trimming the nanolayer channels 382, 386, and 390 therein.

Various techniques may be utilized to process the nanostructure stack 370 of p-type GAA FET 303 to selectively remove the sacrificial nanolayer portions 380, 384, 388, and 392. For example, gate opening 450 may laterally, or otherwise, expose the nanostructure stack 370 of p-type GAA FET 303 while the mask 460 protects the underlying respective p-type GAA FET 323, n-type GAA FET 313, and/or n-type GAA FET 333. Subsequently, the exposed sacrificial nanolayer portions 380, 384, 388, and 392 may be removed to expose the associated nanolayer channels 382, 386, and 390. As depicted in the X cross-section, upper, lower, and side surfaces of nanolayer channels 382, 386, and 390 may be exposed inside or within neighboring inner spacers 396.

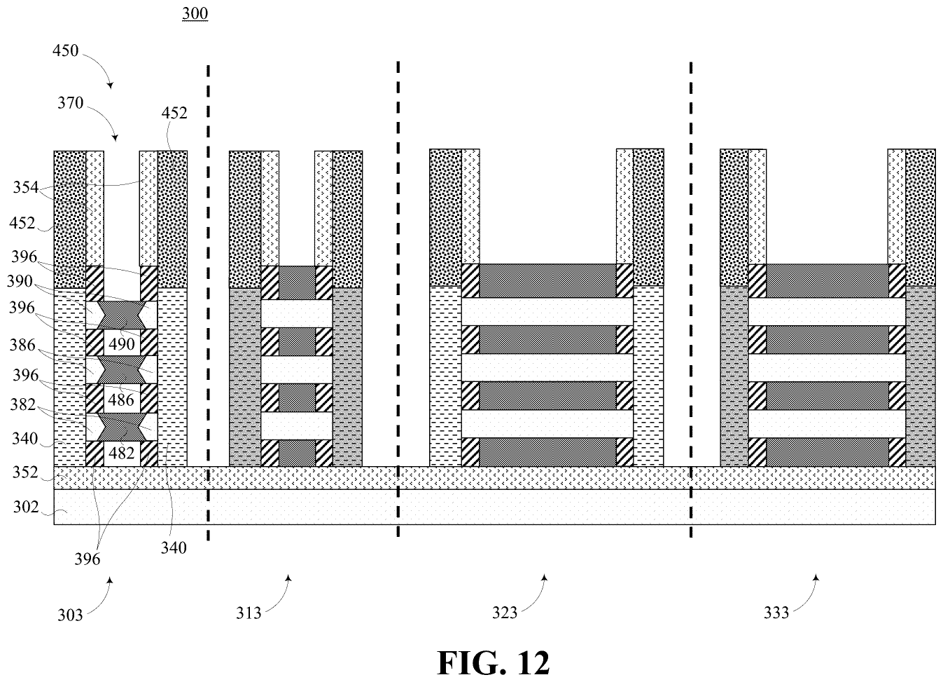

The nanolayer channels 382, 386, and 390 may be trimmed by for example an etch or other selective removal process. The nanolayer channels 382, 386, and 390 may be trimmed to increase the vertical space between adjacent nanolayer channels 382, 386, and 390 prior to cladding, growing, depositing, or otherwise forming, a cladded channel 482, 486, and 490, depicted in FIG. 12, to prevent undesired merging of adjacent nanolayer channels. The trimming of nanolayer channels 382, 386, and 390 can be done either be using a vapor phase etch process, controlled etch cycles, or the like.

FIG. 12 depicts cross-sectional views of semiconductor device 300 shown after exemplary fabrication operation(s), in accordance with one or more embodiments. In the depicted fabrication stage, mask 460 may be removed and nanostructure stack 370 of p-type GAA FET 303 is further processed by forming channel material upon the trimmed nanolayer channels 382, 386, and 390 to form cladded channel 482, 486, and 490, respectively.

Mask 460 may be removed from n-type GAA FET 313, from p-type GAA FET 323, and/or from n-type GAA FET 333 using conventional lithography and etch processes. The removal of mask 460 may reform gate opening 450 of n-type GAA FET 313, p-type GAA FET 323, and n-type GAA FET 333.

Cladded channel 482, 486, and 490 may be formed by epitaxially growing material from applicable surface(s) of the trimmed nanolayer channels 382, 386, and 390 until a desired thickness or shape of growth has been achieved. In a particular implementation, as is exemplarily depicted, cladded channel 482, 486, and 490 may be formed by epitaxially growing SiGe from associated one or more surface(s) of trimmed nanolayer channels 382, 386, and 390. Alternatively, cladded channel 482, 486, and 490 may be formed by deposition of the second material over the trimmed nanolayer channel 382, 386, and 390 material.

In a particular implementation, cladded channels 482, 486, and 490 may include an outer peripheral portion of the second or different channel material relative to an inner core of the first channel material of the trimmed nanolayer channel 382, 386, and 390. For example, cladded channel 482, 486, and 490 may each include a SiGe outer portion around a Si inner core of the trimmed nanolayer channel 382, 386, and 390. In other implementations, as depicted, after forming cladded channels 482, 486, and 490 a thermal mixing process may react the second or different channel material with the first material of the inner core, which causes the second material to diffuse and the first material to be consumed. The thermal mixing process may result in a continuous material (e.g., SiGe) cladded channels 482, 486, and 490, such that a particular second material percentage in one location of the cladded channels 482, 486, and 490 is the same or substantially the same second material percentage in any different location of the cladded channels 482, 486, and 490, respectively.

After the formation of cladded channel 482, the associated channel of p-type GAA FET 303 may include a first portion of nanolayer channel 382 vertically between vertically adjacent inner spacers 396 and in contact with S/D 340, a second portion of nanolayer channel 382 vertically between vertically adjacent inner spacers 396 and in contact with the other S/D 340, and cladded channel 482 in contact with the first portion and second portion of nanolayer channel 382. Similarly, after the formation of cladded channel 486, the associated channel of p-type GAA FET 303 may include a first portion of nanolayer channel 386 vertically between vertically adjacent inner spacers 396 and in contact with S/D 340, a second portion of nanolayer channel 386 vertically between vertically adjacent inner spacers 396 and in contact with the other S/D 340, and cladded channel 490 in contact with the first portion and second portion of nanolayer channel 386. Similarly, after the formation of cladded channel 490, the associated channel of p-type GAA FET 303 may include a first portion of nanolayer channel 390 vertically between vertically adjacent inner spacers 396 and in contact with S/D 340, a second portion of nanolayer channel 390 vertically between vertically adjacent inner spacers 396 and in contact with the other S/D 340, and cladded channel 490 in contact with the first portion and second portion of nanolayer channel 390.

In some implementations (e.g., without thermal mixing, or the like) cladded channel 482, 486, and 490 may include an inner portion that extends and contacts each associated S/D 340 and the cladded portion of the second material surrounding or around the inner portion within at least the gate opening 450.

In a particular implementation, cladded channel 482, 486, and 490 may be formed of SiGe with Ge %, exemplarily ranging from 50% to 70% and may be generally formed of SiGe having a Ge percentage that adequately achieves desired channel mobility of p-type GAA FET 303. In this implementation, respective first portions and second portions of nanolayer channels 382, 386, and 390 may be formed of a different material, such as Si.

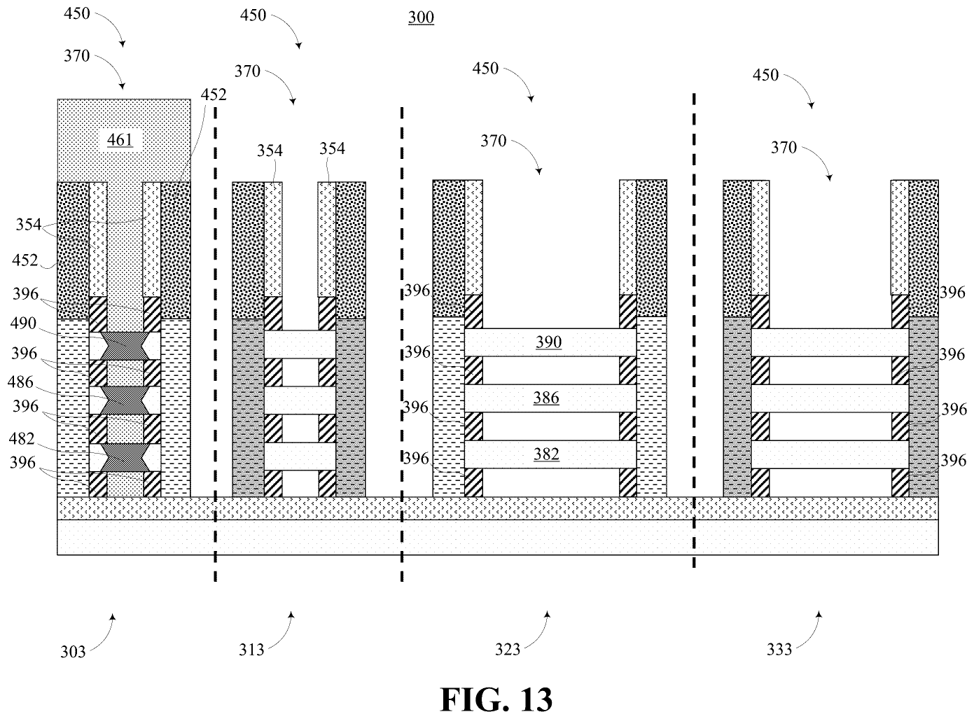

FIG. 13 depicts cross-sectional views of semiconductor device 300 shown after exemplary fabrication operation(s), in accordance with one or more embodiments. In the depicted fabrication stage, mask 461 is formed over p-type GAA FET 303, mask 460 is removed from n-type GAA FET 313, from p-type GAA FET 323, and/or from n-type GAA FET 333, and/or respective nanostructure stacks 370 of n-type GAA FET 313, p-type GAA FET 323, and n-type GAA FET 333 are processed by selectively removing the sacrificial nanolayer portions 380, 384, 388, and 392 therein.

Mask 461 may be a dielectric material, organic planarization material, or mask material, and may be formed by mask material deposition over p-type GAA FET 303. The mask 461 material may be deposited upon p-type GAA FET 303 S/D caps 452, gate spacers 354, upon and around nanostructure stacks 370, upon BDI 352, and/or upon respective STI regions. The material of mask 461 may be etch selective to the material of mask 460, to remove mask 460 while at least temporarily retaining mask 461. The mask 461 may be formed within gate opening 450 of p-type GAA FET 303.

Respective nanostructure stacks 370 of n-type GAA FET 313, p-type GAA FET 323, and n-type GAA FET 333 may be processed by selectively removing the sacrificial nanolayer portions 380, 384, 388, and 392 therein. For example, gate opening 450 may be reformed by the removal of mask 460 and expose the nanostructure stacks 370. Subsequently, the exposed sacrificial nanolayer portions 380, 384, 388, and 392 may be removed to expose the nanolayer channels 382, 386, and 390 within the nanostructure stack 370. As depicted, respective upper and lower surfaces, along with side surfaces, of nanolayer channels 382, 386, and 390 may be exposed inside or within neighboring inner spacers 396 associated with opposing sides of the respective nanostructure stack 370.

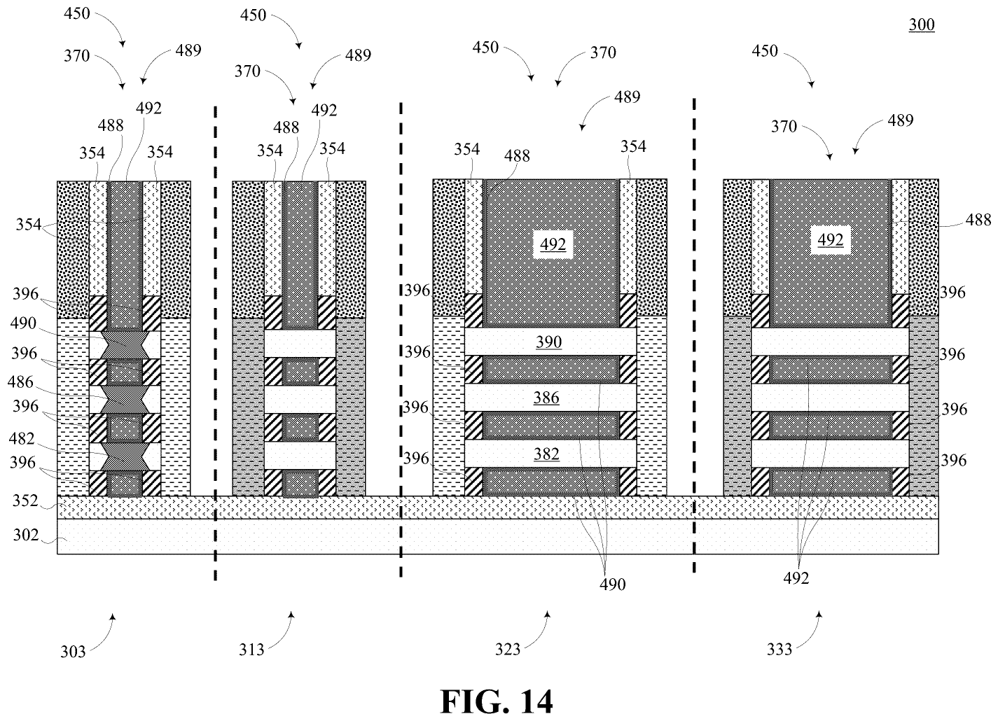

FIG. 14 depicts cross-sectional views of semiconductor device 300 shown after exemplary fabrication operation(s), in accordance with one or more embodiments. In the depicted fabrication stage, replacement gate structure 489 is formed within gate opening 450 around nanolayer channels 382, 386, and 390.

Replacement gate structure 489 can include a gate dielectric 488 and gate conductor 492. Gate dielectric 488 can comprise any suitable dielectric material, including but not limited to silicon oxide, silicon nitride, silicon oxynitride, high-k materials, or any combination of these materials. The gate dielectric 488 can be formed by any suitable deposition process or the like. In some embodiments, the gate dielectric 488 has a thickness ranging from 1 nm to 5 nm, although less thickness and greater thickness are also conceived.

Gate conductor 492 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Gate conductor 492 may further comprise dopants that are incorporated during or after deposition, as appropriate for inclusion within p-type GAA FET 303, n-type GAA FET 313, p-type GAA FET 323, and n-type GAA FET 333, respectively. In some embodiments, the gate conductor 492 may further comprise a workfunction setting layer (not shown) between the gate dielectric 488 and gate conductor 492. The workfunction setting layer can be a workfunction metal (WFM). The gate conductor 492 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

Replacement gate structure 489 may be formed by initially forming the gate dielectric layer within gate opening 450 around the channels 382, 386, and 390, upon sidewalls of inner spacers 396, upon gate spacers 354, and upon the top surface of BDI 352. Replacement gate structure 489 may further be formed by subsequently forming a gate conductor layer upon the gate dielectric layer. For clarity, replacement gate structure 489 may be a wraparound gate structure, gate all around structure, since the gate conductor 392 wraps around the cladded channel 482, 486, and 490 and channels 382, 386, and 390, respectively.

The gate conductor layer and gate dielectric layer may be patterned using conventional lithography and etch process to remove undesired portions and retain desired portion(s), respectively. The retained desired portion(s) of the gate conductor layer and gate dielectric layer may form the gate dielectric layer 390 and gate conductor 392 of the replacement gate structure 392. The etch process, or another subtractive removal technique, may remove undesired portions of replacement gate structure 489, such that a top surface of replacement gate structure 489 is coplanar with the top surface of semiconductor device 300.

In some implementations, gate conductor 392 can be recessed below the top surface of semiconductor device 300 and a dielectric gate cap (not shown) can be formed upon the recessed gate conductor 392.

For clarity, semiconductor device 300 includes heterogenous channels within the same regions, such as p-type regions. A first GAA FET includes a plurality of first channels of a first channel material (e.g., SiGe cladded channels 482, 486, and 490). A second GAA FET includes a plurality of second channels of a second channel material (e.g., Si channels 382, 386, and 390). The similar region GAA FETs with heterogenous channels may have different channel structures, such as relatively different channel lengths. For example, the first GAA FET may include short channels and the second GAA FET may include long channels, where the length of the long channels is greater than the length of the short channels. The embodiments of the present disclosure may provide improved p-type GAA FET device performance by improving p-type GAA FET channel mobility and by reducing channel trim defects within long channel GAA FETs.

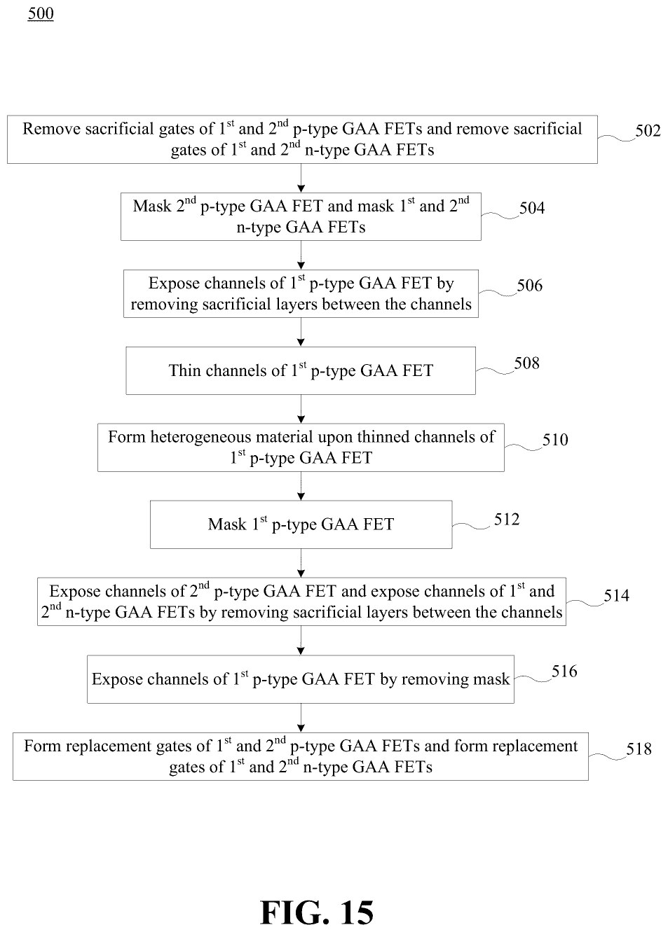

FIG. 15 depicts a flow diagram illustrating method 500 of fabricating semiconductor device 300, according to one or more embodiments of the present disclosure. The depicted fabrication operations of method 500 are illustrated and described above with reference to one or more of FIG. 1 through FIG. 14 of the drawings. Method 500 depicted herein is exemplary. There can be many variations to the diagram or operations described therein without departing from the spirit of the embodiments. For instance, the operations can be performed in a differing order, or operations can be added, deleted or modified.

At block 502, method 500 may include removing sacrificial gate of a first p-type GAA FET (e.g., p-type GAA FET 303), removing sacrificial gate of a second p-type GAA FET (e.g., p-type GAA FET 323), removing sacrificial gate of a first n-type GAA FET (e.g., n-type GAA FET 313), and removing sacrificial gate of a second n-type GAA FET (e.g., n-type GAA FET 333).

At block 504, method 500 may include masking the second p-type GAA FET, masking the first n-type GAA FET, and masking the second n-type GAA FET. At block 506, method 500 may include exposing the channels 382, 386, and 390 of a first material within the first p-type GAA FET by removing sacrificial nanolayer portions 380, 384, 388, and 392, thereby forming gate trench 450.

At block 508, method 500 may include thinning the thickness of channels 382, 386, and 390 within the first p-type GAA FET. At block 510, method 500 may include forming cladded channels 482, 486, and 490 by depositing a second material upon the channels 382, 386, and 390 within the first p-type GAA FET.

At block 512, method 500 may include masking the first p-type GAA FET. At block 514, method 500 may include exposing the channels 382, 386, and 390 of the first material within the second p-type GAA FET, within the first n-type GAA FET, and within the second n-type GAA FET by removing the mask and by removing respective sacrificial nanolayer portions 380, 384, 388, and 392.

At block 516, method 500 may include exposing the cladded channels 482, 486, and 490 within the first p-type GAA FET by removing the mask. At block 518, method 500 may include forming a replacement gate structure 489 around the cladded channels 482, 486, and 490 within the first p-type GAA FET, forming a replacement gate structure 489 around the channels 382, 386, and 390 within the second p-type GAA FET, forming a replacement gate structure 489 around the channels 382, 386, and 390 within the first n-type GAA FET, and with forming a replacement gate structure 489 around the channels 382, 386, and 390 within the second n-type GAA FET.

FIGS. 16-23 depict a semiconductor device 600 after various fabrication operations. For example, semiconductor device 600 depicted in FIG. 16 may have previously undergone similar fabrication operations to those depicted in FIGS. 1-5. As depicted in FIG. 16, semiconductor device 600 may include substrate 602, BDI 652, nanostructure stack 670, S/D 640, S/D cap 652, a sacrificial gate structure, and/or gate spacer 654. Nanostructure stack 670 may include sacrificial nanolayer portions 680, 684, and 688, and 692. Nanostructure stack 670 may further include nanolayer channels 682, 686, and 690. Nanostructure stack 670 may further include inner spacers 696.

For clarity, substrate 602, BDI 652, nanostructure stack 670, S/D 640, S/D cap 752, sacrificial gate structure, and/or gate spacer 654 may be formed of similar material(s) and by similar fabrication techniques described with reference to associated features of semiconductor device 100.

Semiconductor device 600 may include GAA FET 603, GAA FET 605, and GAA FET 607. GAA FET 603, GAA FET 605, and GAA FET 607 may be formed upon the same substrate 602 and/or BDI 652. For clarity, GAA FET 603, GAA FET 605, and GAA FET 607 are formed in the same region type (e.g., p-type region, n-type region, etc.) but may be formed in the same region or location, or different regions or locations of semiconductor device 600, as depicted.

FIG. 16 depicts cross-sectional views of semiconductor device 600 shown after exemplary fabrication operation(s), in accordance with one or more embodiments. In the depicted fabrication stage, a gate opening 750 is formed.

Gate opening 750 may be formed by removing sacrificial gate structure and may expose at least respective sections of the upper surface of STI regions, respective sidewall surface sections of BDI 652, respective sidewall surface sections of sacrificial nanolayer portions 680, 684, 688, and 692, and respective sidewall surface sections of nanolayer channels 682, 686, and 690. In other words, gate opening 750 may expose the side surfaces of BDI 652, sacrificial nanolayer portions 680, 684, 688, and 392, and nanolayer channels 682, 686, and 690. Gate opening 450 may further expose the top surface of sacrificial nanolayer portion 692. Gate opening 750 may further expose at least an inner portion or inside facing portion of gate spacer 654.

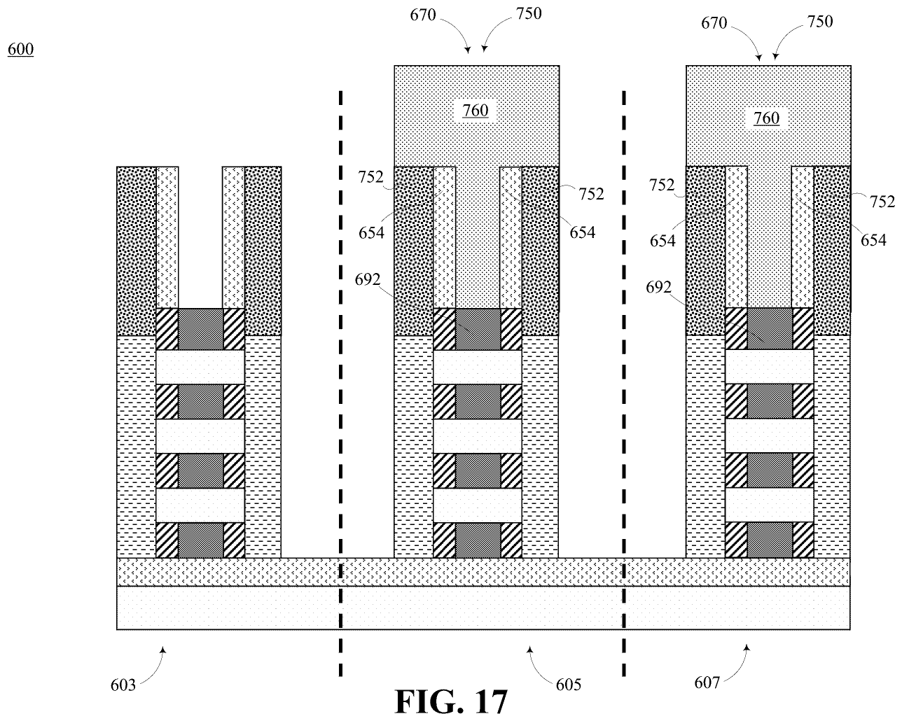

FIG. 17 depicts cross-sectional views of semiconductor device 600 shown after exemplary fabrication operation(s), in accordance with one or more embodiments. In the depicted fabrication stage, mask 460 is formed over GAA FET 605 and over GAA FET 607.

Mask 760 may be a dielectric material, organic planarization material, or other mask material, and may be formed by depositing a blanket mask material over GAA FET 603, GAA FET 605, and GAA FET 607. The mask material may be deposited upon respective S/D caps 752, upon respective gate spacers 654, upon and around respective nanostructure stacks 670, upon respective BDI 652, and/or upon respective STI regions. A portion of the mask material may be subsequently removed over GAA FET 603, thereby reforming gate opening 750 thereof.

Mask 760 may protect GAA FET 605, and GAA FET 607 from subsequent channel processing of GAA FET 603.

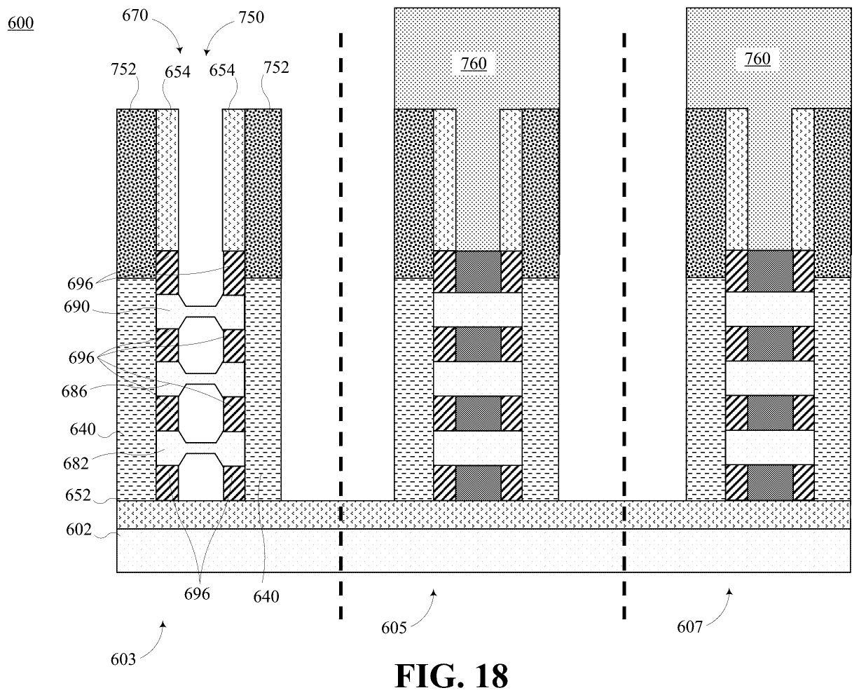

FIG. 18 depicts cross-sectional views of semiconductor device 600 shown after exemplary fabrication operation(s), in accordance with one or more embodiments. In the depicted fabrication stage, nanostructure stack 670 of GAA FET 603 is processed by selectively removing the sacrificial nanolayer portions 680, 684, 688, and 692 and by trimming the nanolayer channels 682, 686, and 690 therein.

Various techniques may be utilized to process the nanostructure stack 670 of GAA FET 603 to selectively remove the sacrificial nanolayer portions 680, 684, 688, and 692. For example, gate opening 750 may laterally, or otherwise, expose the nanostructure stack 670 of GAA FET 603 while the mask 760 protects the underlying respective GAA FET 605 and GAA FET 607. Subsequently, the exposed sacrificial nanolayer portions 680, 684, 688, and 692 may be removed to expose the associated nanolayer channels 682, 686, and 690. As depicted, upper, lower, and side surfaces of nanolayer channels 682, 686, and 690 may be exposed inside or within neighboring inner spacers 696.

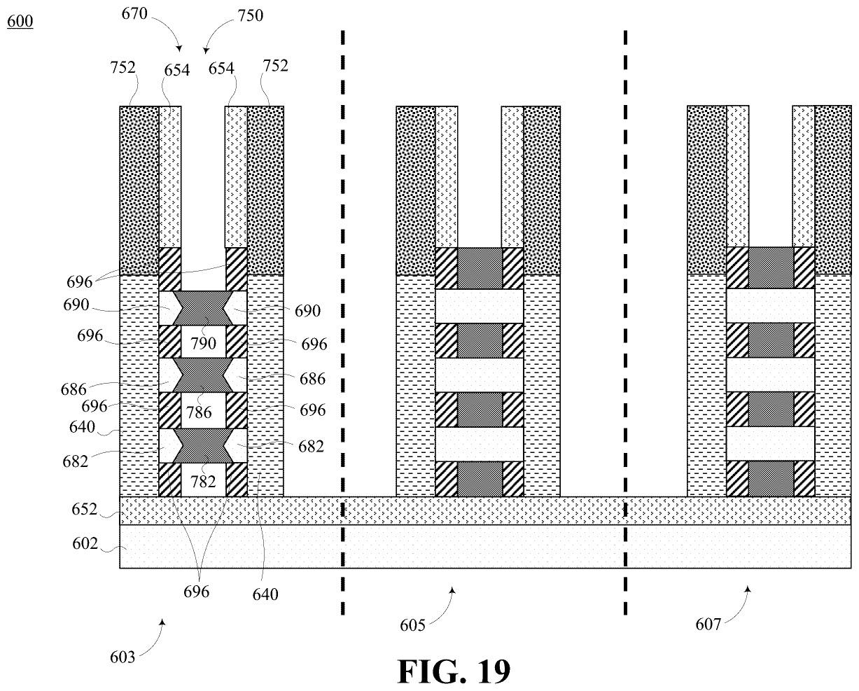

The nanolayer channels 682, 686, and 690 may be trimmed by for example an etch or other selective removal process. The nanolayer channels 682, 686, and 690 may be trimmed to increase the vertical space above/below nanolayer channels 682, 686, and 690 prior to cladding, growing, depositing, or otherwise forming, a cladded channel 782, 786, and 790, depicted in FIG. 19, to prevent undesired merging of adjacent nanolayer channels. The trimming of nanolayer channels 682, 686, and 690 can be done either be using a vapor phase etch process, controlled etch cycles, or the like.

FIG. 19 depicts cross-sectional views of semiconductor device 600 shown after exemplary fabrication operation(s), in accordance with one or more embodiments. In the depicted fabrication stage, nanostructure stack 670 of GAA FET 603 is further processed by removing mask 760 and forming channel material upon the trimmed nanolayer channels 682, 686, and 690 to form cladded channel 782, 786, and 790, respectively.

Mask 760 may be removed from n-type GAA FET 313, from GAA FET 603 and/or from GAA FET 607 using conventional lithography and etch processes. The removal of mask 760 may reform gate opening 750 of GAA FET 603 and/or from GAA FET 607.

Cladded channel 782, 786, and 790 may be formed by epitaxially growing material from applicable surface(s) of the trimmed nanolayer channels 682, 686, and 690 until a desired thickness or shape of growth has been achieved. In a particular implementation, as is exemplarily depicted, cladded channel 782, 786, and 790 may be formed by epitaxially growing SiGe from associated one or more surface(s) of trimmed nanolayer channels 682, 686, and 690. Alternatively, cladded channel 782, 786, and 790 may be formed by deposition of the second material over the trimmed nanolayer channel 682, 686, and 690 material.

In a particular implementation, cladded channels 782, 786, and 790 may include an outer peripheral portion of the second or different channel material relative to an inner core of the first channel material of the trimmed nanolayer channel 682, 686, and 690. For example, cladded channel 782, 786, and 790 may each include a SiGe outer portion around a Si inner core of the trimmed nanolayer channel 682, 686, and 690. In other implementations, as depicted, after forming cladded channels 782, 786, and 790 a thermal mixing process may react the second or different channel material with the first material of the inner core, which causes the second material to diffuse and the first material to be consumed. The thermal mixing process may result in a continuous material (e.g., SiGeₓ) cladded channels 782, 786, and 790, such that a particular second material percentage in one location of the cladded channels 782, 786, and 790 is the same or substantially the same second material percentage in any different location of the cladded channels 782, 786, and 790, respectively.

After the formation of cladded channel 782 the associated channel of GAA FET 603 may include a first portion of nanolayer channel 782 vertically between vertically adjacent inner spacers 696 and in contact with S/D 640, a second portion of nanolayer channel 682 vertically between vertically adjacent inner spacers 696 and in contact with the other S/D 640, and cladded channel 482 in contact with the first portion and second portion of nanolayer channel 382.

Similarly, after the formation of cladded channel 786, the associated channel of GAA FET 603 may include a first portion of nanolayer channel 686 vertically between vertically adjacent inner spacers 696 and in contact with S/D 640, a second portion of nanolayer channel 686 vertically between vertically adjacent inner spacers 696 and in contact with the other S/D 640, and cladded channel 786 in contact with the first portion and second portion of nanolayer channel 686.

Similarly, after the formation of cladded channel 790, the associated channel of GAA FET 603 may include a first portion of nanolayer channel 690 vertically between vertically adjacent inner spacers 696 and in contact with S/D 640, a second portion of nanolayer channel 690 vertically between vertically adjacent inner spacers 696 and in contact with the other S/D 640, and cladded channel 790 in contact with the first portion and second portion of nanolayer channel 690.

In some implementations (e.g., without thermal mixing, or the like) cladded channels 782, 786, and 790 may respectively include an inner portion that extends and contacts each associated S/D 640 and the cladded portion of the second material surrounding or around the inner portion within at least the gate openings 750.

In a particular implementation, cladded channel 782, 786, and 790 of GAA FET 603 may be formed of SiGeₓ with a first Ge % which may be a first Ge percentage that adequately achieves desired channel mobility of GAA FET 603. In this implementation, respective first portions and second portions of nanolayer channels 682, 686, and 690 may be formed of a different material, such as Si, within GAA FET 603.

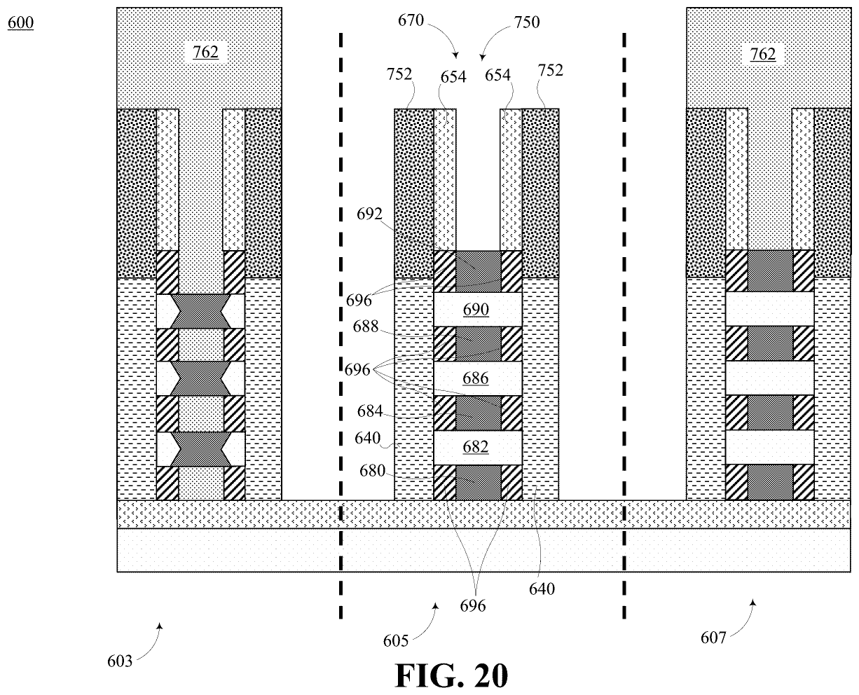

FIG. 20 depicts cross-sectional views of semiconductor device 600 shown after exemplary fabrication operation(s), in accordance with one or more embodiments. In the depicted fabrication stage, mask 762 is formed over GAA FET 603 and/or over GAA FET 607.

Mask 762 may be a dielectric material, organic planarization material, or mask material, and may be formed by mask material deposition over GAA FET 603. The mask 762 material may be deposited upon GAA FET 603 S/D caps 752, gate spacers 654, upon and around nanostructure stacks 670, upon BDI 652, and/or upon respective STI regions within GAA FET 603. The mask 762 may be formed within gate opening 750 of GAA FET 603 and/or within gate opening 750 of GAA FET 607.

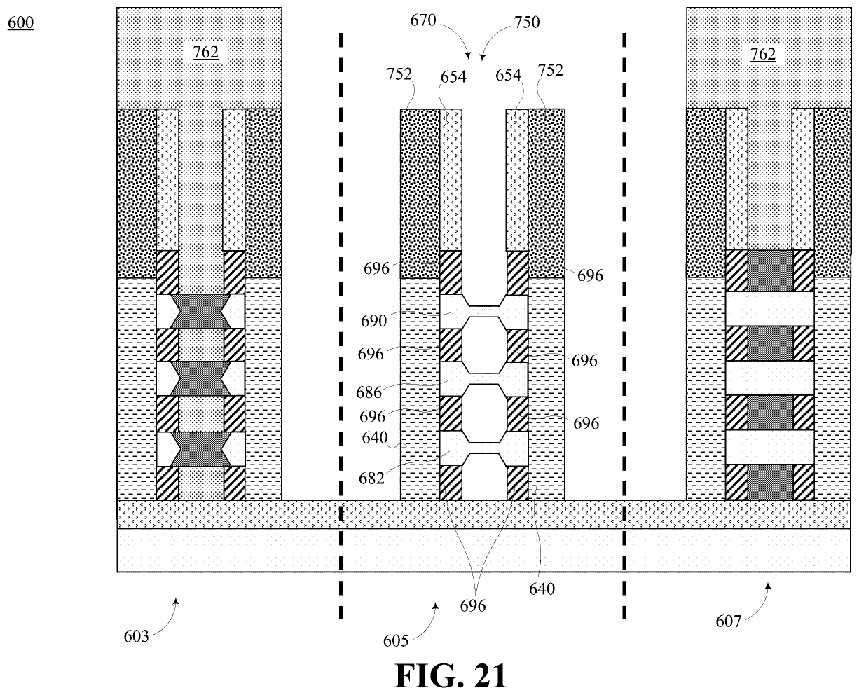

FIG. 21 depicts cross-sectional views of semiconductor device 600 shown after exemplary fabrication operation(s), in accordance with one or more embodiments. In the depicted fabrication stage, nanostructure stack 670 of GAA FET 605 is processed by selectively removing the sacrificial nanolayer portions 680, 684, 688, and 692 and by trimming the nanolayer channels 682, 686, and 690 therein.

Various techniques may be utilized to process the nanostructure stack 670 of GAA FET 605 to selectively remove the sacrificial nanolayer portions 680, 684, 688, and 692. For example, gate opening 750 may laterally, or otherwise, expose the nanostructure stack 670 of GAA FET 605 while the mask 762 protects the underlying respective GAA FET 603 and/or GAA FET 607. Subsequently, the exposed sacrificial nanolayer portions 680, 684, 688, and 692 may be removed to expose the associated nanolayer channels 682, 686, and 690 within GAA FET 605. As depicted, upper, lower, and side surfaces of nanolayer channels 682, 686, and 690 may be exposed inside or within neighboring inner spacers 696.

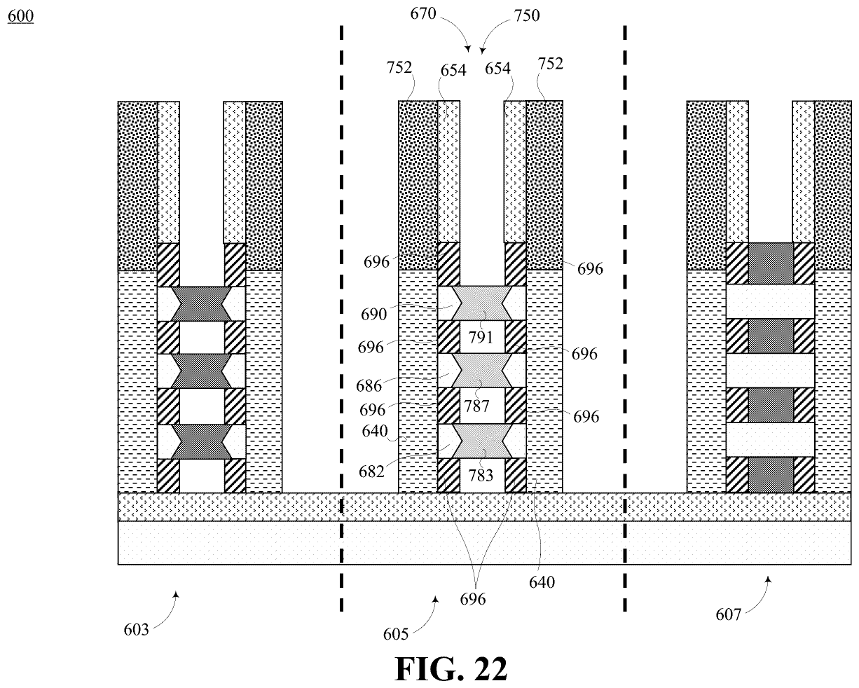

The nanolayer channels 682, 686, and 690 may be trimmed by for example an etch or other selective removal process. The nanolayer channels 682, 686, and 690 may be trimmed to increase the vertical space above/below nanolayer channels 682, 686, and 690 prior to cladding, growing, depositing, or otherwise forming, a cladded channel 783, 787, and 791, depicted in FIG. 22, to prevent undesired merging of adjacent nanolayer channels. The trimming of nanolayer channels 682, 686, and 690 can be done either be using a vapor phase etch process, controlled etch cycles, or the like.

FIG. 22 depicts cross-sectional views of semiconductor device 600 shown after exemplary fabrication operation(s), in accordance with one or more embodiments. In the depicted fabrication stage, mask 762 is removed and nanostructure stack 670 of GAA FET 605 is further processed by and forming channel material upon the trimmed nanolayer channels 682, 686, and 690 to form cladded channel 783, 787, and 791, respectively.

Mask 762 may be removed from GAA FET 602 and/or GAA FET 607 using conventional lithography and etch processes. The removal of mask 762 may reform gate opening 750 of GAA FET 603 and/or from GAA FET 607.

Cladded channel 783, 787, and 791 may be formed by epitaxially growing material from applicable surface(s) of the trimmed nanolayer channels 682, 686, and 690 until a desired thickness or shape of growth has been achieved. In a particular implementation, as is exemplarily depicted, cladded channel 783, 787, and 791 may be formed by epitaxially growing SiGe from associated one or more surface(s) of trimmed nanolayer channels 682, 686, and 690. Alternatively, cladded channel 783, 787, and 791 may be formed by deposition of the second material over the trimmed nanolayer channel 682, 686, and 690 material.

In a particular implementation, cladded channels 783, 787, and 791 may include an outer peripheral portion of the second or different channel material relative to an inner core of the first channel material of the trimmed nanolayer channel 682, 686, and 690. For example, cladded channel 783, 787, and 791 may each include a SiGe_{y} outer portion around a Si inner core of the trimmed nanolayer channel 682, 686, and 690. In other implementations, as depicted, after forming cladded channels 783, 787, and 791 a thermal mixing process may react the second or different channel material with the first material of the inner core, which causes the second material to diffuse and the first material to be consumed. The thermal mixing process may result in a continuous material (e.g., SiGe_{y}) cladded channels 783, 787, and 791, such that a particular second material percentage in one location of the cladded channels 783, 787, and 791 is the same or substantially the same second material percentage in any different location of the cladded channels 783, 787, and 791 respectively.

After the formation of cladded channel 783 the associated channel of GAA FET 605 may include a first portion of nanolayer channel 682 vertically between vertically adjacent inner spacers 696 and in contact with S/D 640, a second portion of nanolayer channel 682 vertically between vertically adjacent inner spacers 696 and in contact with the other S/D 640, and cladded channel 783 in contact with the first portion and second portion of nanolayer channel 682.

Similarly, after the formation of cladded channel 787, the associated channel of GAA FET 605 may include a first portion of nanolayer channel 686 vertically between vertically adjacent inner spacers 696 and in contact with S/D 640, a second portion of nanolayer channel 686 vertically between vertically adjacent inner spacers 696 and in contact with the other S/D 640, and cladded channel 787 in contact with the first portion and second portion of nanolayer channel 686.

Similarly, after the formation of cladded channel 791, the associated channel of GAA FET 605 may include a first portion of nanolayer channel 690 vertically between vertically adjacent inner spacers 696 and in contact with S/D 640, a second portion of nanolayer channel 690 vertically between vertically adjacent inner spacers 696 and in contact with the other S/D 640, and cladded channel 791 in contact with the first portion and second portion of nanolayer channel 690.

In some implementations (e.g., without thermal mixing, or the like) cladded channels 783, 787, and 791 may respectively include an inner portion that extends and contacts each associated S/D 640 and the cladded portion of the second material surrounding or around the inner portion within at least the gate opening 750.

In a particular implementation, cladded channel 783, 787, and 791 of GAA FET 605 may be formed of SiGe_{y} with a second Ge % that adequately achieves desired channel mobility of GAA FET 605 and that is different relative to SiGeₓ with the first Ge % of cladded channel 782, 786, and 790 of GAA FET 603. In this implementation, respective first portions and second portions of nanolayer channels 682, 686, and 690 may be formed of a different material, such as Si, within GAA FET 605.

In some implementations, a liner such as an oxide liner may be formed around the cladded channels 782, 786, and 790 of GAA FET 603 and/or around the nanolayer channels 682, 686, and 690 of GAA FET 607 to protect such channels from epitaxial growth therefrom, prior to the formation of cladded channels 783, 787, and 791 of GAA FET 605.

FIG. 23 depicts cross-sectional views of semiconductor device 600 shown after exemplary fabrication operation(s), in accordance with one or more embodiments. In the depicted fabrication stage, replacement gate structure 489 is formed within gate opening 450 around respective nanolayer channels of GAA FETs 603, 605, and/or 607.

Respective nanostructure stacks 370 of GAA FET 607 may be processed by selectively removing the sacrificial nanolayer portions 680, 684, 688, and 692 therein. As depicted, respective upper and lower surfaces, along with side surfaces, of nanolayer channels 682, 686, and 690 may be exposed inside or within neighboring inner spacers 696 associated with opposing sides of the respective nanostructure stack 670 of GAA FET 607.

Replacement gate structure 789 can include a gate dielectric 788 and gate conductor 792. Gate dielectric 788 can comprise any suitable dielectric material, including but not limited to silicon oxide, silicon nitride, silicon oxynitride, high-k materials, or any combination of these materials. The gate dielectric 788 can be formed by any suitable deposition process or the like. In some embodiments, the gate dielectric 788 has a thickness ranging from 1 nm to 5 nm, although less thickness and greater thickness are also conceived.

Gate conductor 792 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Gate conductor 792 may further comprise dopants that are incorporated during or after deposition, as appropriate for inclusion within GAA FETs 603, 605, and/or 607, respectively. In some embodiments, the gate conductor 792 may further comprise a workfunction setting layer (not shown) between the gate dielectric 788 and gate conductor 792. The workfunction setting layer can be a workfunction metal (WFM). The gate conductor 792 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

Within GAA FET 603, replacement gate structure 689 may be formed by initially forming the gate dielectric layer around the cladded channels 782, 786, and 790, upon sidewalls of inner spacers 696, upon gate spacers 654, upon the top surface of BDI 652, and upon STI region(s) within gate opening 750. Within GAA FET 605, the gate dielectric layer may be formed around the cladded channels 783, 787, and 791, upon sidewalls of inner spacers 696, upon gate spacers 654, upon the top surface of BDI 652, and upon STI region(s) within gate opening 750. Similarly, within GAA FET 607, the gate dielectric layer may be formed around the channels 682, 686, and 690, upon sidewalls of inner spacers 696, upon gate spacers 654, upon the top surface of BDI 652, and upon STI region(s) within gate opening 750.

Replacement gate structures 489 within GAA FETs 603, 605, and/or 607 may further be formed by subsequently forming a gate conductor layer upon the gate dielectric layer. For clarity, replacement gate structure 489 may be a wraparound gate structure, gate all around structure, since the gate conductor wraps around the cladded channels 782, 786, and 790, around the cladded channels 783, 787, and 791, and/or wraps around the channels 682, 686, and 690, respectively.

The gate conductor layer and gate dielectric layer may be patterned using conventional lithography and etch process to remove undesired portions and retain desired portion(s), respectively. The retained desired portion(s) of the gate conductor layer and gate dielectric layer may form the gate dielectric layer 790 and gate conductor 792 of the replacement gate structures 689. The etch process, or another subtractive removal technique, may remove undesired portions of replacement gate structure 689, such that a top surface of replacement gate structure 689 is coplanar with the top surface of semiconductor device 600.

In some implementations, gate conductor 792 can be recessed below the top surface of semiconductor device 600 and a dielectric gate cap (not shown) can be formed upon the recessed gate conductor 792.

For clarity, semiconductor device 600 includes heterogenous channels within the same regions, such as p-type regions. A first GAA FET includes a plurality of first channels of a first channel material (e.g., SiGeₓ cladded channels 782, 786, and 790 each, with a first Ge % or concentration). A second GAA FET includes a plurality of second channels of a second channel material (e.g., SiGe_{y} cladded channels 783, 787, and 791 each, with a second Ge % or concentration different from the first Ge % or concentration). A third GAA FET includes a plurality of third channels of a third channel material (e.g., Si channels 682, 686, and 690). The similar region GAA FETs with heterogenous channels may have different channel structures, such as relatively different channel lengths. For example, GAA FET 603 may be a short channel GAA FET, GAA FET 603 may have an intermedial length channel or a mid-channel GAA FET, and GAA FET 607 may be a long channel GAA FET.

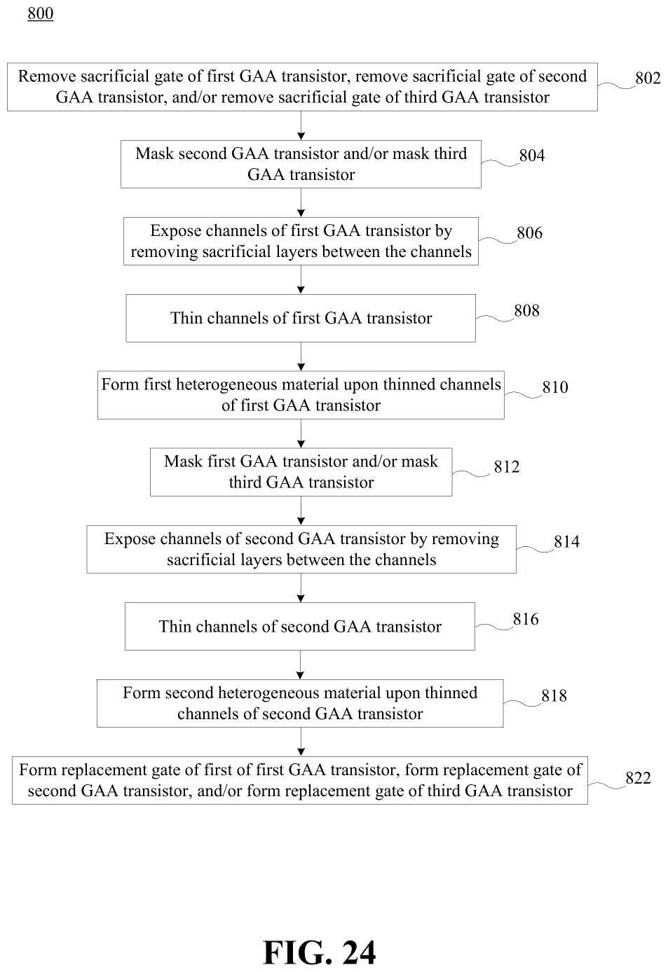

FIG. 24 depicts a flow diagram illustrating method 800 of fabricating semiconductor device 600, according to one or more embodiments of the present disclosure. The depicted fabrication operations of method 800 are illustrated and described above with reference to one or more of FIG. 1 through FIG. 8 and/or FIG. 16 through FIG. 23 of the drawings. Method 800 depicted herein is exemplary. There can be many variations to the diagram or operations described therein without departing from the spirit of the embodiments. For instance, the operations can be performed in a differing order, or operations can be added, deleted or modified.

At block 802, method 800 may include removing sacrificial gates of GAA FET 603, GAA FET 605, and/or GAA FET 607. At block 804, method 800 may include masking GAA FET 605, and/or GAA FET 607. At block 806, method 800 may include exposing the channels 682, 686, and 690 of a first material (e.g. Si, etc.) within GAA FET 603 by removing sacrificial nanolayer portions 680, 684, 688, and 692, thereby forming gate trench 450 therein.

At block 808, method 800 may include thinning the thickness of channels 682, 686, and 690 within GAA FET 603. At block 810, method 800 may include removing the mask of GAA FET 605 and/or of GAA FET 607 and forming cladded channels 782, 786, and 790 by depositing a second material (e.g., SiGeₓ) of a first concentration upon the channels 682, 686, and 690 within GAA FET 603.

At block 812, method 800 may include masking GAA FET 603 and/or GAA FET 607. At block 814, method 800 may include exposing the channels 682, 686, and 690 of the first material within GAA FET 605 by removing sacrificial nanolayer portions 680, 684, 688, and 692 therein.

At block 816, method 800 may include thinning the thickness of channels 682, 686, and 690 within GAA FET 605. At block 818, method 800 may include removing the mask of GAA FET 603 and/or GAA FET 607 and forming cladded channels 783, 787, and 791 by depositing the second material (e.g., SiGe_{y}) of a second concentration upon the channels 682, 686, and 690 within GAA FET 605.

At block 822, method 800 may include forming a replacement gate structure 689 around the cladded channels 782, 786, and 790 within GAA FET 603, forming a replacement gate structure 689 around cladded channels 783, 787, and 791 within GAA FET 605, and/or forming a replacement gate structure 689 around the channels 682, 686, and 690 within GAA FET 607.

FIG. 25 through FIG. 27 depict a semiconductor device 900 after various fabrication operations. For ease of illustration, semiconductor device 900 as is depicted in FIG. 26 includes a GAA FET 903 that includes nanolayer channels 1082, 1086, and 1090 of a first channel material in a particular region type (e.g., p-type region), a GAA FET 905 that includes nanolayer channels 1081, 1085, and 1089 of a second channel material in the same particular region type, and/or a GAA FET 907 that includes nanolayer channels 1083, 1087, and 1091 of a third channel material in the same particular region type. Semiconductor device 900 with long channels are depicted in FIG. 27.

Semiconductor device 900 may further include substrate 902, BDI 952, S/D 940, S/D cap 1052, a replacement gate structure 989, gate spacer 954, and/or inner spacers 996. Replacement gate structure 989 can include a gate dielectric 1088 and gate conductor 1092.

For clarity, respective end surfaces of each of the nanolayer channels 1082, 1086, and 1090 may contact S/D 940. For example, as depicted, a respective left end surface of each of the nanolayer channels 1082, 1086, and 1090 may contact a source and a respective right end surface of each of the nanolayer channels 1082, 1086, and 1090 may contact a drain. Similarly, a respective left end surface of each of the nanolayer channels 1081, 1085, and 1089 may contact a source and a respective right end surface of each of the nanolayer channels 1081, 1085, and 1089 may contact a drain. Likewise, a respective left end surface of each of the nanolayer channels 1083, 1087, and 1091 may contact a source and a respective right end surface of each of the nanolayer channels 1083, 1087, and 1091 may contact a drain.

For clarity, semiconductor device 900 as depicted in FIG. 26 may be formed with the substrate 902 and nanolayer stack(s) 925 structure, exemplary depicted in FIG. 25, and by further utilizing similar fabrication techniques described with reference to semiconductor device 100.

FIG. 25 depicts cross-sectional views of the semiconductor device 100 after initial fabrication operations in accordance with embodiments of the present disclosure. In the present fabrication stage, one or more nanolayer stacks 925 are formed upon a substrate 902. Further in the present fabrication stage, shallow trench isolation (STI) region(s) may be formed upon the substrate 902 next to nanolayer stacks 925.

Non-limiting examples of suitable materials for the substrate 902 include Si (silicon), strained Si, SiC (silicon carbide), Ge (germanium), SiGe (silicon germanium), SiGe:C (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof. Other non-limiting examples of semiconductor materials include III-V materials, for example, indium phosphide (InP), gallium arsenide (GaAs), aluminum arsenide (AlAs), or any combination thereof. The III-V materials can include at least one “III element,” such as aluminum (Al), boron (B), gallium (Ga), indium (In), and at least one “V element,” such as nitrogen (N), phosphorous (P), arsenic (As), antimony (Sb). The substrate 102 can be a bulk semiconductor material that includes Si.

A bottom sacrificial layer 908 may be formed upon substrate 902. Subsequently, alternating nanostructure layers may be formed upon the bottom sacrificial layer 908. The bottom sacrificial layer 908 may be initially formed over substrate 902. The bottom sacrificial layer 908 may comprise an epitaxial SiGe layer with high Ge %, ranging from 90% to 99%. In some embodiments of the invention, the bottom sacrificial layer 908 is SiGe having a Ge percentage that is sufficiently different from the Ge percentage in the other layers in nanolayer stack(s) 925, such that the bottom sacrificial layer 908 can be selectively removed without also removing the other e.g., SiGe layers in nanolayer stack(s) 925. The bottom sacrificial layer 908 can have a thickness of, for example, from about 4 to about 15 nm.

The nanolayer stack 925 may include portions formed of an alternating series of sacrificial nanolayers, such as SiGe sacrificial nanolayers, and heterogenous nanolayers, such as SiGe and Si heterogenous nanolayers. The sacrificial SiGe nanolayers could have lower Ge % ranging from 70% to 80%, relative to the Ge % of bottom sacrificial layer 908.

Sacrificial portions 910, 914, 918, and 922 of each nanolayer stack 125 may be formed from an associated sacrificial nanolayer and heterogenous nanostructure portions 930, 932, and 934 of each nanolayer stack 925 may be formed from an associated heterogenous nanolayer.

Semiconductor device 900 may include GAA FET region 903, GAA FET region 905, and/or GAA FET region 907. GAA FET region 903, GAA FET region 905, and/or GAA FET region 907 are generally the same region type (e.g., all p-type regions), but may be in different, same, or similar locations within semiconductor device 900.

Heterogenous nanostructure portions 930, 932, and 934 generally include different or heterogenous materials within the different GAA FET region 903, GAA FET region 905, and/or GAA FET region 907. For example, heterogenous nanostructure portion 930 includes a first nanostructure portion 912 (e.g., SiGe with Ge % concentration 40% to 60%) within GAA FET region 903, a second nanostructure portion 911 (e.g., SiGe with Ge % concentration 10% to 30%) within GAA FET region 905, and/or a third nanostructure portion 913 (e.g., Si) within GAA FET region 907. Similarly, heterogenous nanostructure portion 932 includes a first nanostructure portion 916 (e.g., SiGe with Ge % concentration 40% to 60%) within GAA FET region 903, a second nanostructure portion 915 (e.g., SiGe with Ge % concentration 10% to 30%) within GAA FET region 905, and/or a third nanostructure portion 917 (e.g., Si) within GAA FET region 907. Likewise, heterogenous nanostructure portion 934 includes a first nanostructure portion 920 (e.g., SiGe with Ge % concentration 40% to 60%) within GAA FET region 903, a second nanostructure portion 919 (e.g., SiGe with Ge % concentration 10% to 30%) within GAA FET region 905, and/or a third nanostructure portion 921 (e.g., Si) within GAA FET region 907.

In accordance with embodiments of the disclosure, the bottom sacrificial layer 908 may be epitaxially grown from the substrate 902, the sacrificial nanolayer that which sacrificial portion 910 is formed may be epitaxially grown therefrom, one or more GAA FET region 903, GAA FET region 905, and/or GAA FET region 907 may be masked as appropriate, and sequentially exposed to form the heterogenous nanolayer that which heterogenous nanostructure portion 930 is formed. Subsequently, the sacrificial nanolayer that which sacrificial portion 914 may be formed, one or more GAA FET region 903, GAA FET region 905, and/or GAA FET region 907 may be masked as appropriate, and sequentially exposed so as to form the heterogenous nanolayer that which heterogenous nanostructure portion 932 is formed. Subsequently, the sacrificial nanolayer that which sacrificial portion 918 may be formed, one or more GAA FET region 903, GAA FET region 905, and/or GAA FET region 907 may be masked as appropriate, and sequentially exposed so as to form the heterogenous nanolayer that which heterogenous nanostructure portion 934 is formed. Subsequently, the sacrificial nanolayer that which sacrificial portion 934 may be formed.

These various layers may then be patterned by removing respective undesired portion(s) or section(s) of the aforementioned layers while retaining respective desired portions. The removal of undesired portions of the bottom sacrificial layer and the alternating sacrificial nanolayers and heterogenous nanolayers can be accomplished using, for example, conventional lithography and etch process. The removal of such undesired portions may further remove undesired portions of substrate 902. Desired portions of bottom sacrificial layer 908 and the alternating sacrificial nanolayers and heterogenous nanolayers may be retained, thereby forming the one or more nanolayer stacks 925.

Subsequently, STI regions may be formed over the substrate 902 and adjacent to the one or more nanolayer stacks 925. A top surface of one or more STI regions may be coplanar with a bottom surface of bottom sacrificial portion(s) 908 of one or more nanolayer stacks 925. STI regions may be formed by depositing STI dielectric material upon the substrate 902 and adjacent to the nanolayer stacks 925, followed by STI dielectric material etch back, recess, or the like. STI regions may electrically isolate components or features of neighboring GAA FETs, or the like.

For clarity, semiconductor device 900 as depicted in FIG. 26 and FIG. 27 may be formed with the substrate 902 and nanolayer stack(s) 925 structure, exemplary depicted in FIG. 25, and by further utilizing exemplary fabrication techniques described with reference to semiconductor device 100 and FIGS. 2-8. In so doing, semiconductor device 900 as depicted in FIG. 26 and as depicted in FIG. 27, may be fabricated, and generally includes heterogenous channels within the same regions, such as p-type regions, that may or may not be in the same location within semiconductor device 900. Semiconductor device 900 includes a first GAA FET with a plurality of first channels of a first channel material (e.g., SiGeₓ nanolayer channels 1082, 1086, and 1090 each, with a first Ge % or concentration). Semiconductor device 900 may include a second GAA FET with a plurality of second channels of a second channel material (e.g., SiGe_{y} channels 1081, 1085, and 1089 each, with a second Ge % or concentration different from the first Ge % or concentration) or may include a third GAA FET with a plurality of third channels of a third channel material (e.g., Si channels 1083, 1087, and 1091). The similar region GAA FETs with heterogenous channels may have different channel structures, such as relatively different channel lengths.

For clarity, in an implementation, semiconductor device 900 may include a short channel GAA FET 903 with SiGeₓ or SiGe_{y} cladded channels 1082, 1086, 1090 and/or a short channel GAA FET 905 with SiGeₓ or SiGe_{y} cladded channels 1081, 1085, 1089 and a long channel GAA FET 907 with SE nanolayer channels 1083, 1087, 1091 all within the same p-type region, but not necessarily the same p-type region location.

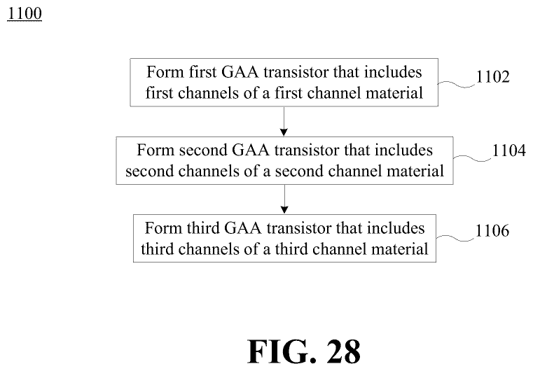

FIG. 28 depicts a flow diagram illustrating method 1100 of fabricating a semiconductor device, according to one or more embodiments of the present disclosure. The depicted fabrication operations of method 1100 are illustrated and described above with reference to one or more of the structural FIGs of the drawings. Method 1100 depicted herein is exemplary. There can be many variations to the diagram or operations described therein without departing from the spirit of the embodiments. For instance, the operations can be performed in a differing order, or operations can be added, deleted or modified.

At block 1102, method 1100 includes forming a first GAA FET with a plurality of first channels of a first channel material. At block 1104, method 1100 further includes forming a second GAA FET with a plurality of second channels of a second channel material and/or forming a third GAA FET that with plurality of third channels of a third channel material (block 1106). For example, a first p-type GAA FET with SiGeₓ channels is formed, a second p-type GAA FET with SiGe_{y} (i.e., with the SiGeₓ representing an intentionally or predetermined different concentration or % Ge relative to SiGe_{y}) is formed, and/or a third p-type GAA FET with Si channels is formed.

The descriptions of the various embodiments of the present disclosure have been presented for purposes of illustration but are not intended to be exhaustive or limited to the embodiments described. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments described herein.

What is claimed is:

1. A semiconductor device comprising:
a first gate all around field effect transistor (GAA FET) within a first region of a first type, the first GAA FET comprising a plurality of first nanostructure channels of a first channel material; and
a second GAA FET within a second region of the first type, the second GAA FET comprising a plurality of second nanostructure channels of a second channel material different than the first channel material.

2. The semiconductor device of claim 1, further comprising:
a third GAA FET within a third region of the first type, the third GAA FET comprising a plurality of third nanostructure channels of a third channel material different than the first channel material and different than the second channel material.

3. The semiconductor device of claim 2, wherein the first region is a p-type region and wherein the second region is a p-type region.

4. The semiconductor device of claim 3, wherein the third region is a p-type region.

5. The semiconductor device of claim 3, wherein the first channel material is Silicon Germanium with a first Ge percentage (SiGeₓ) and wherein the second channel material is Silicon Germanium with a second Ge percentage (SiGe_{y}).

6. The semiconductor device of claim 4, wherein the first channel material is Silicon Germanium with a first Ge percentage (SiGeₓ), wherein the second channel material is Silicon Germanium with a second Ge percentage (SiGe_{y}), and wherein the third channel material is Silicon (Si).

7. The semiconductor device of claim 1, wherein the plurality of second nanostructure channels each have a longer channel length relative to the plurality of first nanostructure channels.

8. The semiconductor device of claim 2, wherein the plurality of third nanostructure channels each have a longer channel length relative to the plurality of first nanostructure channels.

9. The semiconductor device of claim 6, wherein the first GAA FET further comprises a first portion of nanolayer channel between each of the plurality of first nanostructure channels and a first source and drain.

10. The semiconductor device of claim 9, wherein the second GAA FET further comprises a second portion of nanolayer channel between each of the plurality of second nanostructure channels and a second source and drain.

11. The semiconductor device of claim 10, wherein each of the plurality of third nanostructure channels directly contact a third source and drain.

12. A semiconductor device comprising:
a first gate all around field effect transistor (GAA FET) within a first p-type region, the first GAA FET comprising a plurality of Silicon Germanium (SiGe) nanostructure channels; and
a second GAA FET within a second p-type region, the second GAA FET comprising a plurality of Silicon nanostructure channels.

13. The semiconductor device of claim 12, wherein the plurality of Silicon nanostructure channels each have a same channel length relative to the plurality of SiGe nanostructure channels.

14. The semiconductor device of claim 12, wherein the plurality of Silicon nanostructure channels each have a longer channel length relative to the plurality of SiGe nanostructure channels.

15. The semiconductor device of claim 12, wherein the first GAA FET further comprises a Si portion of nanolayer channel between each of the plurality of SiGe nanostructure channels and a first source and drain.

16. The semiconductor device of claim 13, wherein each of the plurality of Si nanostructure channels directly contact a second source and drain.

17. The semiconductor device of claim 12, further comprising a third GAA FET within a n-type region, the third GAA FET comprising one or more Silicon nanostructure channels.

18. The semiconductor device of claim 17, wherein the one or more Silicon nanostructure channels each have a same channel length relative to the plurality of SiGe nanostructure channels.

19. The semiconductor device of claim 17, wherein the one or more Silicon nanostructure channels each have a longer channel length relative to the plurality of SiGe nanostructure channels.

20. A semiconductor device fabrication method comprising:
forming a first gate all around field effect transistor (GAA FET) within a first region of a first type, the first GAA FET comprising a plurality of first nanostructure channels of a first channel material; and
forming a second GAA FET within a second region of the first type, the second GAA FET comprising a plurality of second nanostructure channels of a second channel material.
